(19) United States
(12) Patent Application Publication
(10) Pub. No.: US 2003/0006413 A1
(43) Pub. Date: Jan. 9, 2003

(54) Semiconductor test system and associated methods for wafer level acceptance testing

(75) Inventors: Ravi Chawla, Atlanta, GA (US); William R. Eisenstadt, Gainesville, FL (US); Robert M. Fox, Gainesville, FL (US); Don F. Hemmenway, Melbourne, FL (US); Jeffrey M. Johnston, Indian Harbour Beach, FL (US); Chris A. McCarty, Melbourne, FL (US)

Correspondence Address: ALLEN, DYER, DOPPELT, MILBRATH & GILCHRIST P.A., 1401 CITRUS CENTER 255 SOUTH ORANGE AVENUE, P.O. BOX 3791, ORLANDO, FL, 32802-3791, US

(73) Assignee: University of Florida, Gainesville, FL (US)

(21) Appl. No.: 10/117,378

(22) Filed: Apr. 3, 2002

Related U.S. Application Data
(60) Provisional application No. 60/282,011, filed on Apr. 6, 2001.

(51) Int. Cl. H01L 23/58

(52) U.S. Cl. 257/48

(57) ABSTRACT

A semiconductor test system includes at least one semiconductor wafer having working dies and at least one test die formed therein. Each of the working dies includes at least one bipolar transistor. A tester selectively supplies a changing direct current (DC) input signal to a selected test die and monitors a DC output signal therefrom. Each test die includes a test oscillator having at least one sample bipolar transistor substantially identical to the bipolar transistors of the working dies. The test oscillator switches between a non-oscillating state and an oscillating state as the DC input signal changes, and generates the DC output signal to the tester indicative of switching between the non-oscillating state and the oscillating state. A threshold level of a bias current that causes the test oscillator to switch between the non-oscillating state and the oscillating state is correlated to the maximum oscillation frequency and the transition frequency of the sample bipolar transistor.

### RELATED APPLICATION

This application is based upon prior filed copending provisional application No. 60/282,011 filed Apr. 6, 2001, the entire disclosure of which is incorporated herein by reference.

### FIELD OF THE INVENTION

The present invention relates to the field of semiconductor test systems, and more particularly, to a test die on a semiconductor wafer for monitoring high frequency parameters of a bipolar transistor.

### BACKGROUND OF THE INVENTION

A processed semiconductor wafer has a large number of working dies formed on a semiconductor substrate. Depending on the size of the wafer, the number of working dies may be between several hundred to more than a thousand. Semiconductor wafers are manufactured in lots, with each lot typically including 20 to 25 wafers. Depending on the number of orders to fill, multiple lots are run. Multiple lots are usually run on different days using different processing equipment. Consequently, it is not uncommon for semiconductor processing variations to be introduced during the individual lot runs.

After a lot run, each semiconductor wafer undergoes a wafer level acceptance test to ensure reliability of the semiconductor processing steps. One approach to performing a wafer level acceptance test is to use at least one test die on each semiconductor wafer. The test dies are also known as drop-in test circuits, and are separate from the working dies on the semiconductor substrate. After the semiconductor wafer has been tested, the working dies are separated from one another, and the test dies are discarded.

The test dies are formed on the wafer at the same time the working dies are formed. Each test die typically includes sample devices that are substantially identical to the devices formed in the working dies. These devices include capacitors, MOS transistors, bipolar transistors and inductors, for example. By testing the sample devices in the test dies at selected areas of each semiconductor wafer, a determination can be made concerning reliability of the semiconductor processing steps for that particular wafer.

A tester, such as a DC tester, selectively interfaces with each test die to provide DC input signals to a test die, and receives DC output signals therefrom. A DC tester is used to test, for example, contact areas and resistivity of the devices. DC testing, also known as DC screening, is relatively straightforward to perform. This allows a test die to be tested in a timely manner at a relatively low cost. However, DC testers are currently not able to determine high frequency parameters of bipolar transistors. Bipolar transistors are commonly used in wireless radio frequency circuits, for example, and may operate at a high frequency, such as in the GHz range.

High frequency parametric testing of bipolar transistors ensures proper operation of these radio frequency type circuits including such transistors. A standard technique for monitoring and or determining high frequency parameters of bipolar transistors involves measuring the s-parameters. The high frequency parameters of a bipolar transistor are then extracted from the measured s-parameters.

Unfortunately, s-parameter test equipment is required to measure the s-parameters of bipolar transistors. DC testers are not compatible with the measured s-parameters. S-parameter testing, although ideal for development purposes, is not ideal for routine monitoring of process parameters during production of semiconductor wafers that include bipolar transistors. S-parameter test equipment is expensive, slows down the wafer level acceptance testing, and is complicated to operate, thus requiring expert microwave technicians. Therefore, there is a need for monitoring high frequency parameters of bipolar transistors during wafer level acceptance testing that is easier, faster and cheaper as compared to using s-parameter test equipment.

### SUMMARY OF THE INVENTION

In view of the foregoing background, it is therefore an object of the present invention to provide a semiconductor test system that includes at least one test die on a semiconductor wafer to be tested, wherein each test die is compatible with a DC tester for monitoring high frequency parameters of a bipolar transistor.

This and other objects, advantages and features according to the present invention are provided by a semiconductor test system comprising at least one semiconductor wafer comprising a plurality of working dies and at least one test die formed therein. Each of the working dies comprises at least one bipolar transistor.

The semiconductor test system further includes a tester for selectively supplying a changing direct current (DC) input signal to a selected test die and monitoring a DC output signal therefrom. Each test die comprises a test oscillator including at least one sample bipolar transistor substantially identical to the bipolar transistors of the working dies. The test oscillator preferably switches between a non-oscillating state and an oscillating state as the DC input signal changes, and generates the DC output signal to the tester indicative of switching between the non-oscillating state and the oscillating state.

A level of the DC input signal preferably increases as the DC input signal changes. Accordingly, the test oscillator switches from the non-oscillating state to the oscillating state as the level of the DC input signal increases.

Each test die preferably comprises a bias current generator for generating a changing bias current to the sample bipolar transistor based upon the changing DC input signal. The test oscillator switches between the non-oscillating and oscillating states based upon a threshold level of the changing bias current generated for the sample bipolar transistor. The threshold level of the changing bias current correlates with at least one high frequency parameter of the sample bipolar transistor.

The semiconductor test system advantageously allows DC measurements to be correlated to high frequency parameters of a bipolar transistor, such as the maximum oscillation frequency f_{MAX} and the transition frequency fₜ. These DC measurements can be used to monitor the process to detect drifts in these process parameters. Using DC measurements to determine high frequency parameters of a sample bipolar transistor avoids having to measure the s-parameters and extracting the high frequency parameters from these measured parameters. The use of specialized s-parameter equipment is inconvenient, time consuming and costly for routine monitoring of a semiconductor process during production.

The test oscillator starts to oscillate as the bias current being applied thereto preferably increases from zero to the threshold level as discussed above. A rise in the DC output signal from the test oscillator may be used to determine the threshold bias current at which the oscillations start. This threshold level of the bias current, also referred as the input oscillation threshold current, is strongly affected by the base resistance and base-emitter capacitance of the sample bipolar transistor under test.

In other words, the threshold level of the bias current at which the test oscillator starts to oscillate is sensitive to the base resistance and the base-emitter capacitance of the sample bipolar transistor. The base-emitter capacitance affects the maximum oscillation frequency f_{MAX}, and the base resistance effects the transition frequency fₜ.

The test die may further comprise a dummy circuit connected to the test oscillator for maintaining a capacitance of the sample bipolar transistor constant as the bias current changes. The test die may also further comprise a detector circuit connected to an output of the test oscillator for generating the DC output signal to the tester. The test oscillator may be a Colpitts oscillator, for example.

Another aspect of the invention is directed to a semiconductor wafer comprising a semiconductor substrate, and a plurality of working dies on the semiconductor substrate. Each of the working dies comprises at least one bipolar transistor. The semiconductor wafer further comprises at least one test die on the semiconductor substrate, and comprises a test oscillator including at least one sample bipolar transistor substantially identical to the bipolar transistors of the working dies. The test oscillator preferably switches between a non-oscillating state and an oscillating state as a DC input signal being applied thereto changes, and generates a DC output signal indicative of switching between the non-oscillating state and the oscillating state.

Yet another aspect of the invention is directed to a method for testing a semiconductor wafer as described above. The method preferably comprises supplying a changing DC input signal to the at least one test die. The test oscillator switches between a non-oscillating state and an oscillating state as the DC input signal changes, and generates a DC output signal indicative of switching between the non-oscillating state and the oscillating state. The method further comprises monitoring the DC output signal from the test die.

### BRIEF DESCRIPTION OF THE DRAWINGS

FIG. 1 is a block diagram of a semiconductor test system in accordance with the present invention.

FIG. 2 is a block diagram of a test circuit formed in the test die illustrated in FIG. 1.

FIG. 3 is a flowchart illustrating the method for testing a semiconductor wafer in accordance with the present invention.

FIG. 4 is a circuit diagram for determining the transition frequency ft of a sample bipolar transistor in accordance with the present invention.

FIG. 5 is a graph of a short-circuit current gain versus frequency in accordance with the present invention.

FIG. 6 is a circuit diagram for determining the maximum oscillation frequency f_{MAX} of a sample bipolar transistor in accordance with the present invention.

FIG. 7 is a block diagram for a positive feedback circuit for an oscillator in accordance with the present invention.

FIG. 8 is a circuit diagram of a Colpitts oscillator in accordance with the present invention.

FIG. 9 is a circuit diagram of an equivalent circuit for a bipolar transistor in accordance with the present invention.

FIG. 10 is a circuit diagram of a modified Colpitts oscillator in accordance with the present invention.

FIG. 11 is a circuit diagram of a test oscillator with a dummy circuit connected thereto in accordance with the present invention.

FIG. 12 is a circuit diagram of only the dummy circuit illustrated in FIG. 11.

FIG. 13 is a circuit diagram of the dummy circuit modified for determining the loop gain thereof in accordance with the present invention.

FIG. 14 is a circuit diagram of the dummy circuit with compensation in accordance with the present invention.

FIG. 15 is a circuit diagram of the bias circuit in accordance with the present invention.

FIG. 16 is a circuit diagram of a detector circuit in accordance with the present invention.

FIG. 17 is a detailed circuit diagram of the test circuit in accordance with the present invention.

FIGS. 18a-b are graphs of the input current for the sample bipolar transistor, and the voltage at the collector of the sample bipolar transistor in accordance with the present invention.

FIGS. 19a-b are graphs of the voltage at the output of the detector circuit, and the voltage at the output of the collector of the sample bipolar transistor in accordance with the present invention.

FIGS. 20a-b are graphs of the collector current for the sample bipolar transistor, and the input current for the sample bipolar transistor in accordance with the present invention.

FIGS. 21a-b are graphs of the collector current for the sample bipolar transistor, and the collector current for the second bipolar transistor in the dummy circuit without RC stabilization in accordance with the present invention.

FIGS. 22a-b are graphs of the collector current for the sample bipolar transistor, and the collector current for the second bipolar transistor in the dummy circuit with RC stabilization in accordance with the present invention.

FIG. 23 is a plot showing the threshold bias current versus the base resistance of the sample bipolar transistor in accordance with the present invention.

FIG. 24 is a circuit diagram of a simulation circuit for allowing Monte Carlo simulations for studying the variations of the maximum operating frequency versus the threshold bias current in accordance with the present invention.

FIG. 25 is a plot showing the threshold bias current versus the maximum operating frequency of the sample bipolar transistor in accordance with the present invention.

FIG. 26 is a plot showing a predicted value of the threshold bias current using a linear model versus the measured threshold bias current in accordance with the present invention.

FIG. 27 is a plot showing the voltage at the output of the detector circuit versus the input bias current in accordance with the present invention.

FIG. 28 illustrates box plots of the threshold bias current for different iterations of revision 1 at different values of the total input bias current in accordance with the present invention.

FIG. 29 illustrates box plots of the threshold bias current for all the iterations of different revisions at a total input bias current of 800 μA in accordance with the present invention.

FIG. 30 is a plot of the measured effective base resistance of the sample bipolar transistor versus the threshold bias current in accordance with the present invention.

FIG. 31 is a plot of the peak value of the maximum oscillating frequency among varying bias points versus the threshold bias current in accordance with the present invention.

FIG. 32 is a plot of the product of the effective base resistance and the base-emitter capacitance of the sample bipolar transistor versus the threshold bias current in accordance with the present invention.

FIG. 33 is a plot of the effective base-emitter capacitance of the sample bipolar transistor versus the threshold bias current in accordance with the present invention.

### DETAILED DESCRIPTION OF THE PREFERRED EMBODIMENTS

The present invention will now be described more fully hereinafter with reference to the accompanying drawings, in which preferred embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like numbers refer to like elements throughout.

The determination of high frequency parameters of bipolar transistors is an important step in production testing to ensure reliability of the semiconductor process and proper operation of radio frequency (RF) circuits that includes these transistors. High frequency parameters of a bipolar transistor include, for example, the maximum oscillation frequency f_{MAX} and the transition frequency fₜ.

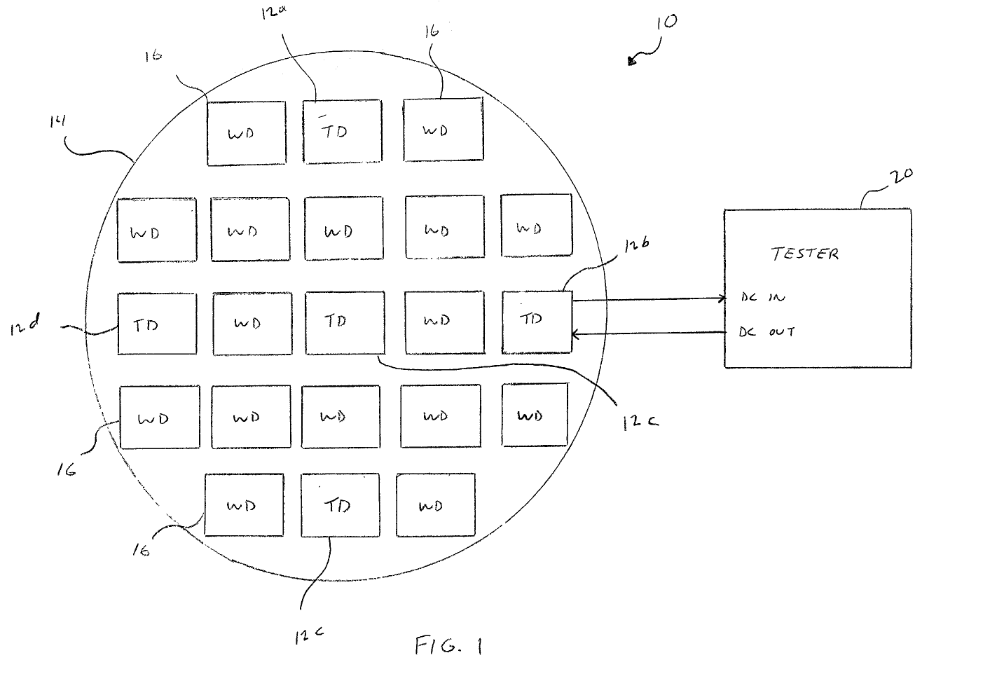

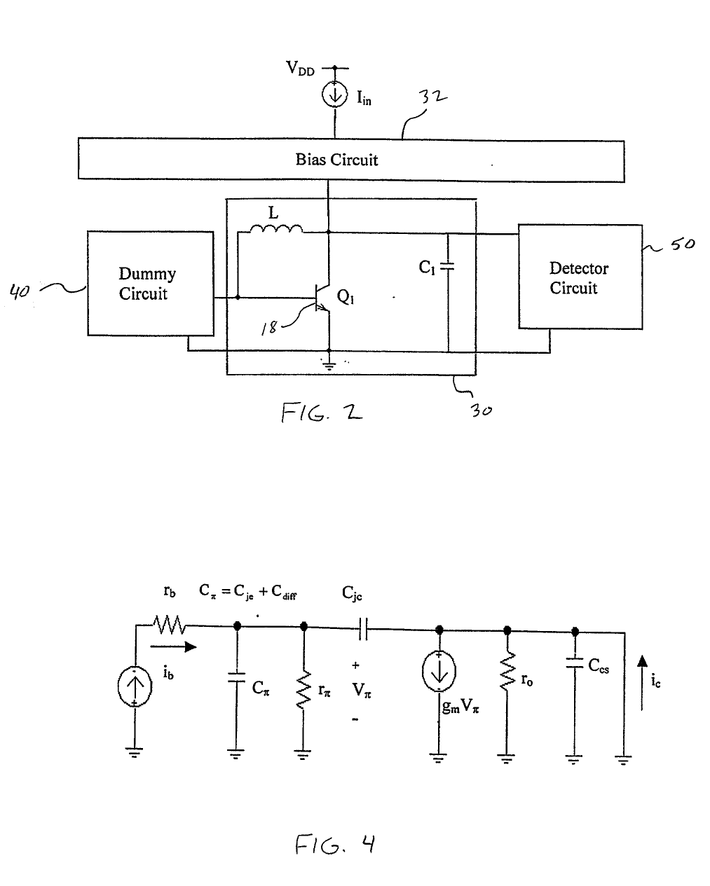

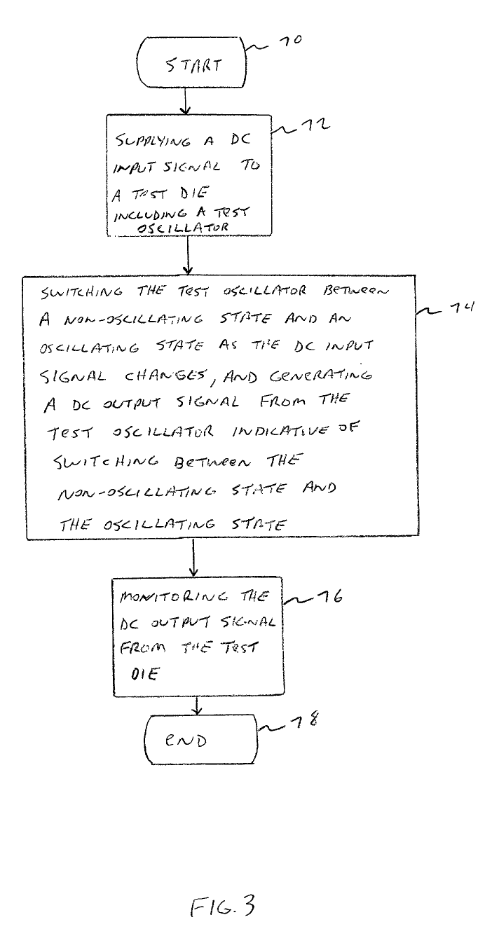

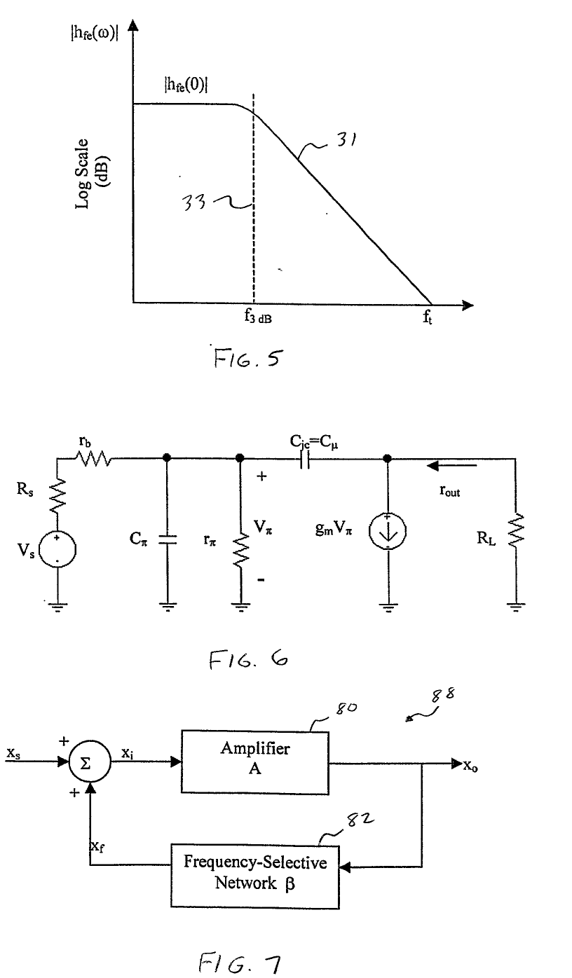

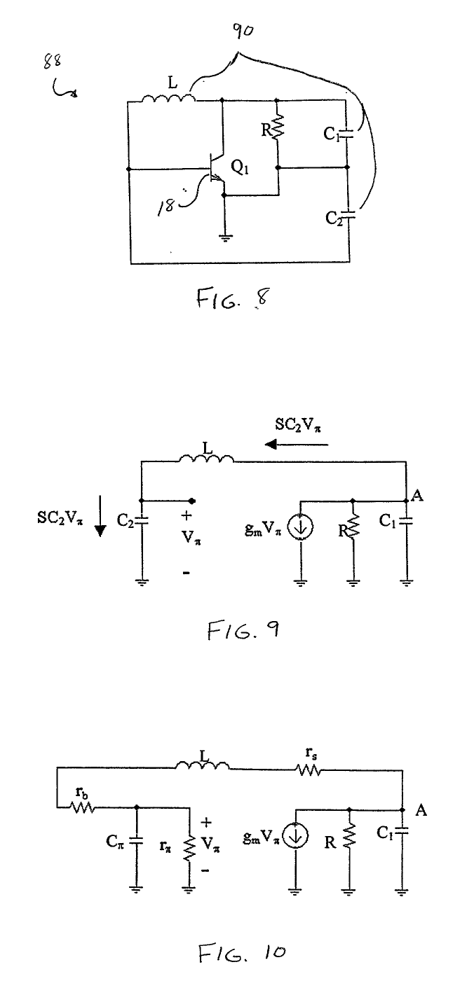

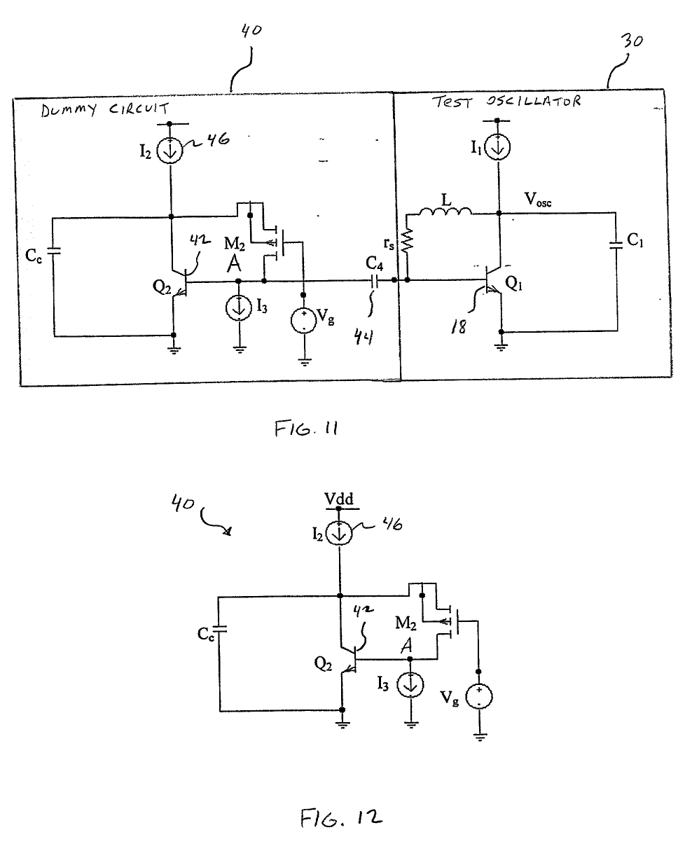

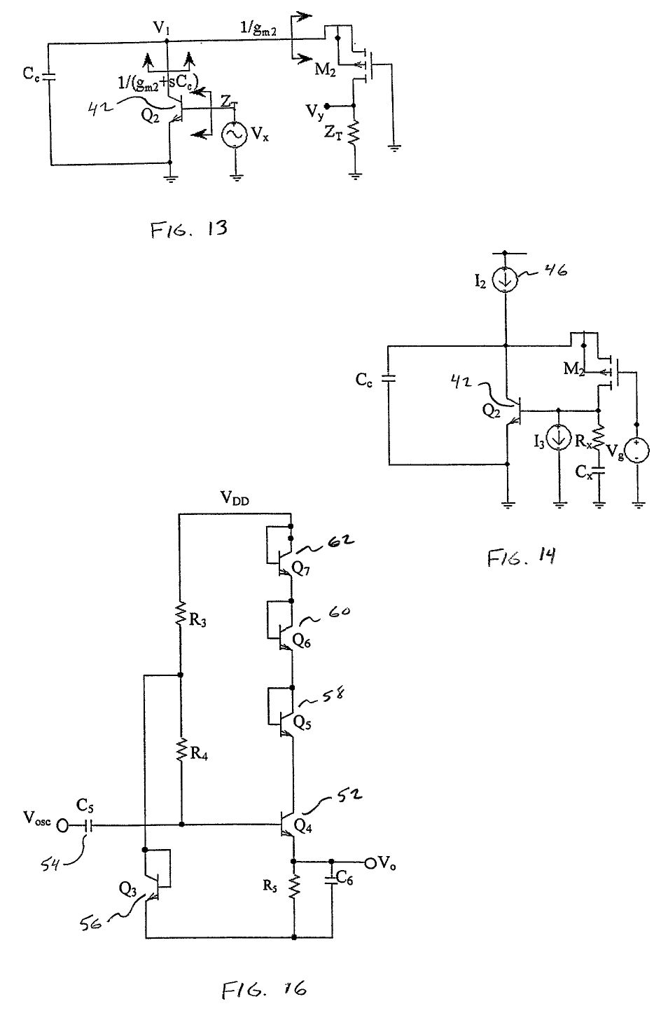

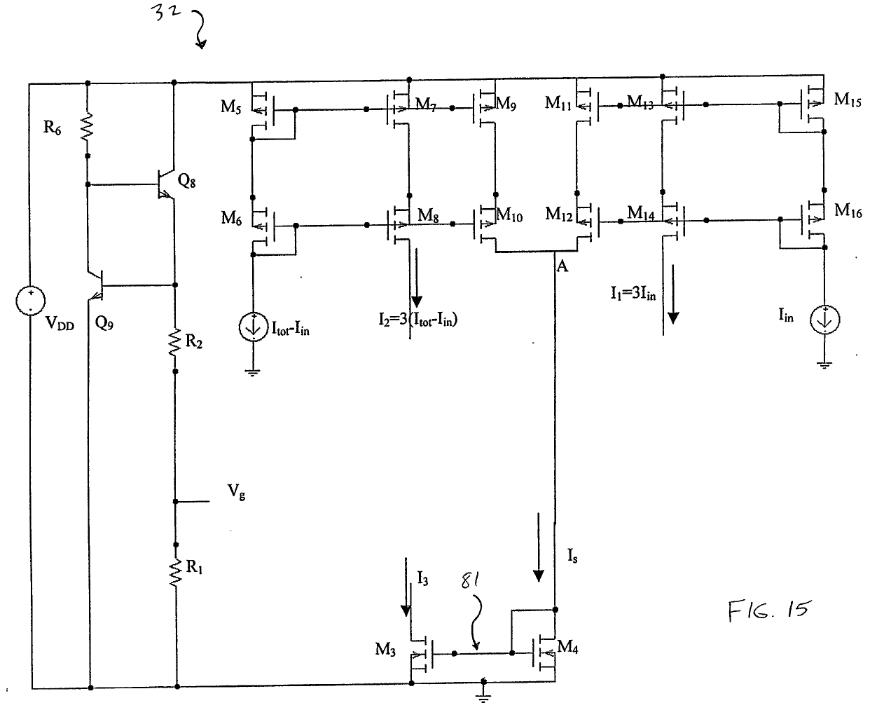

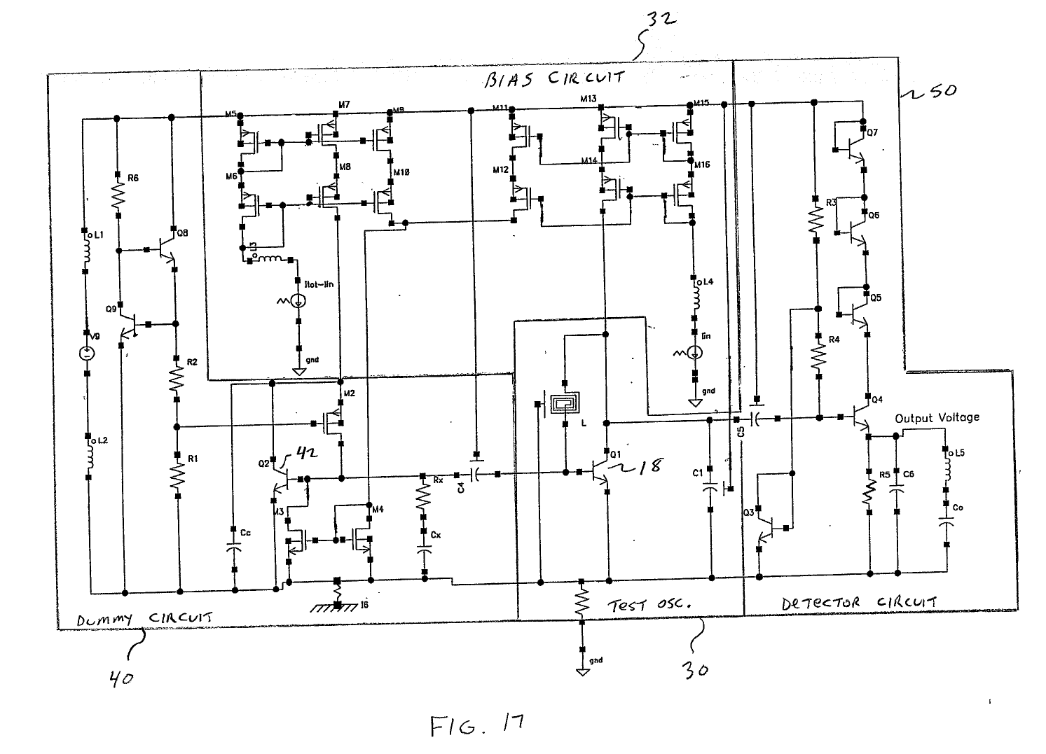

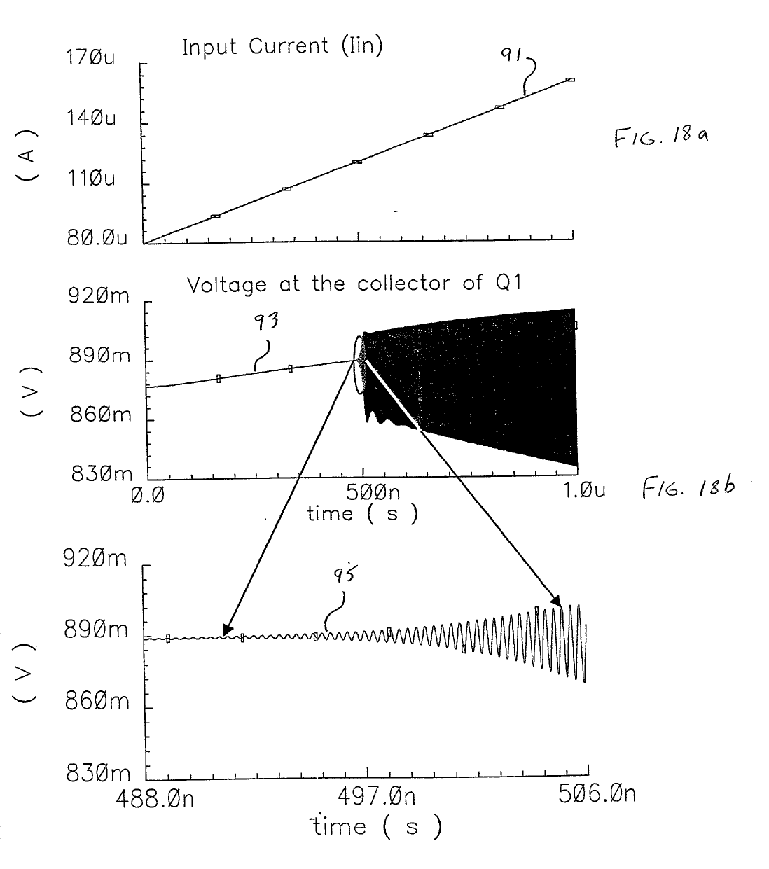

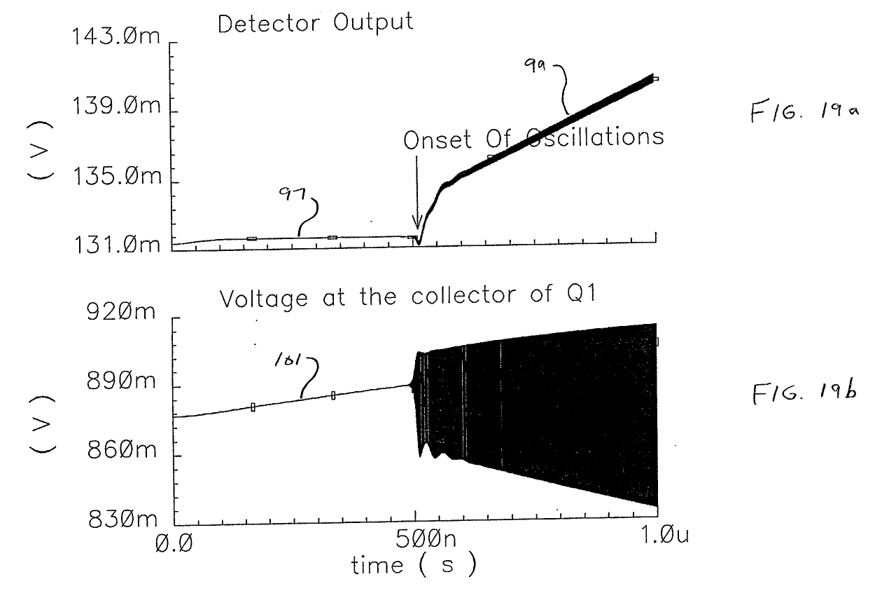

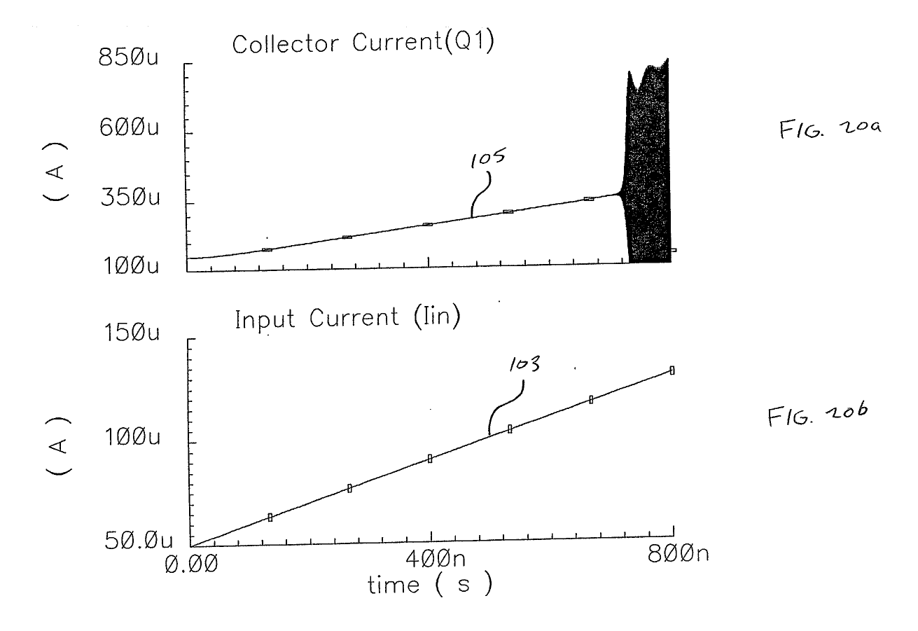

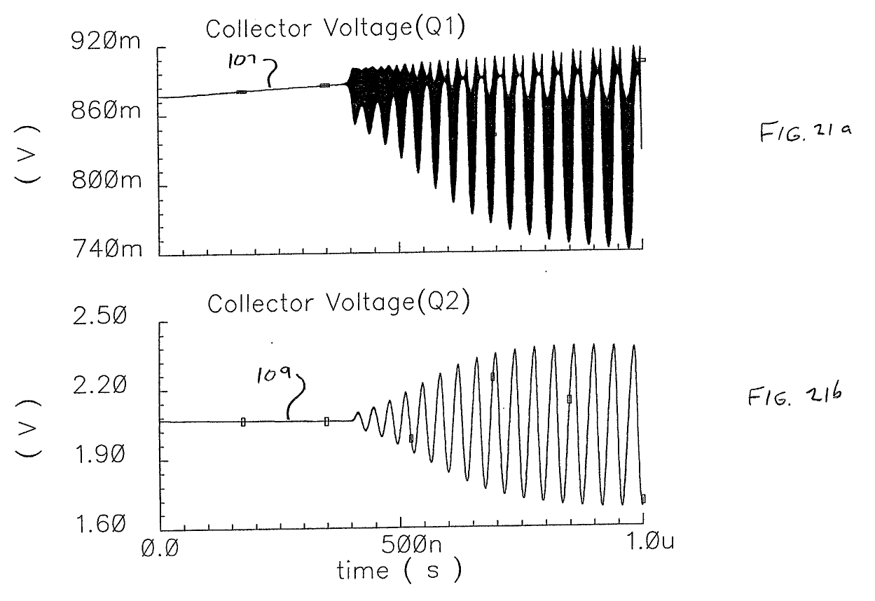

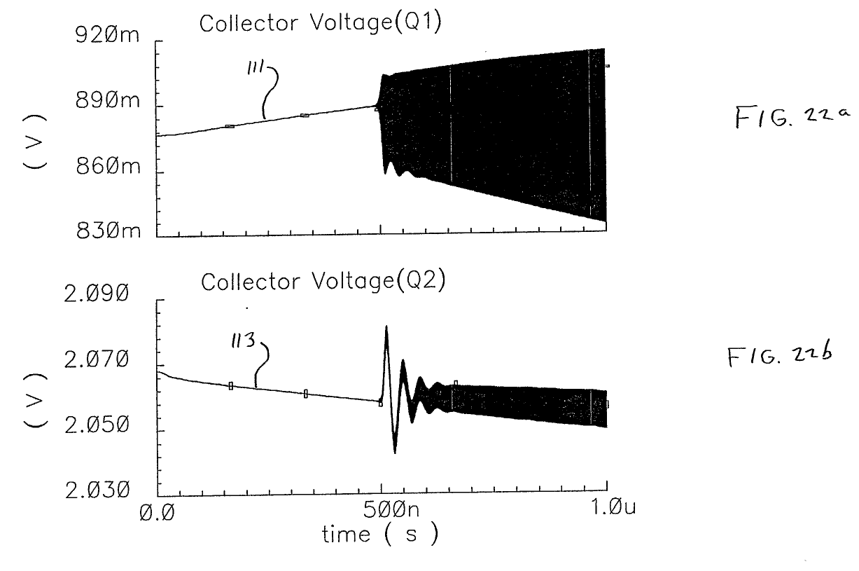

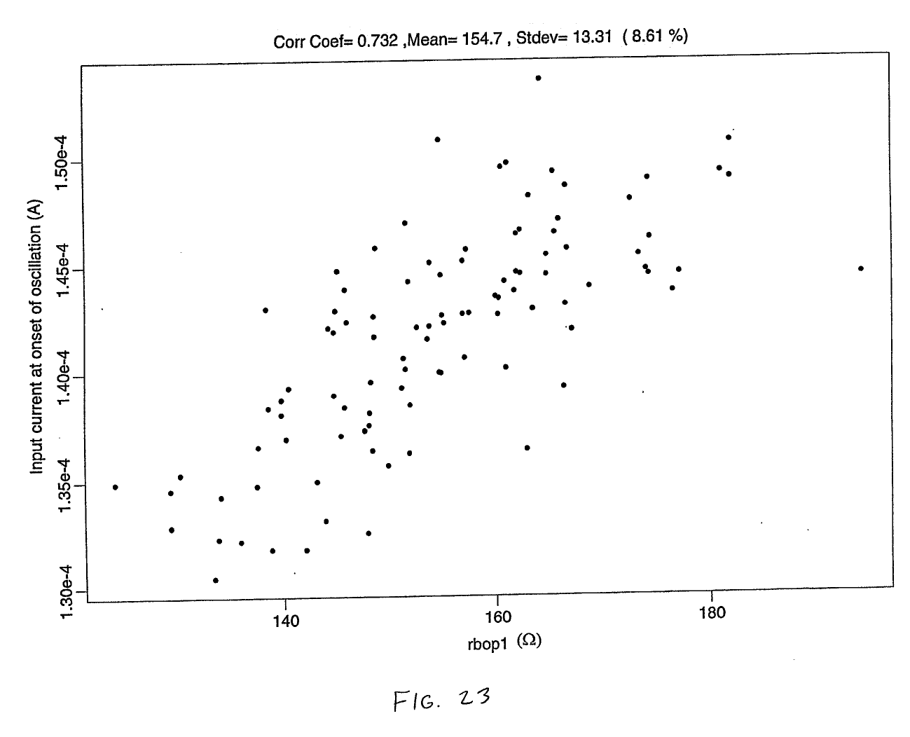

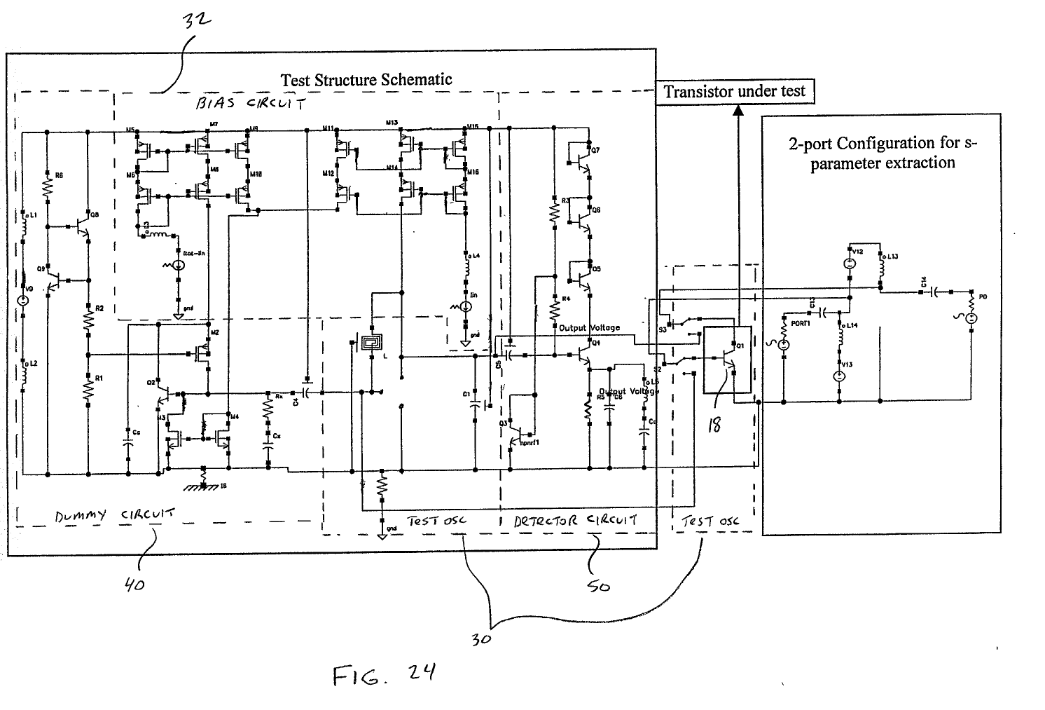

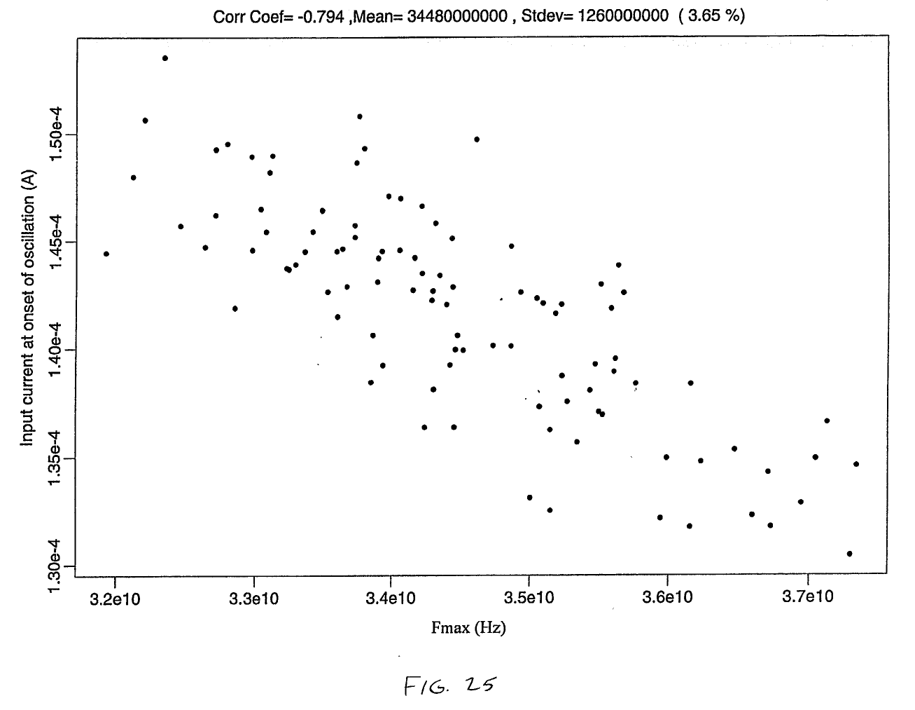

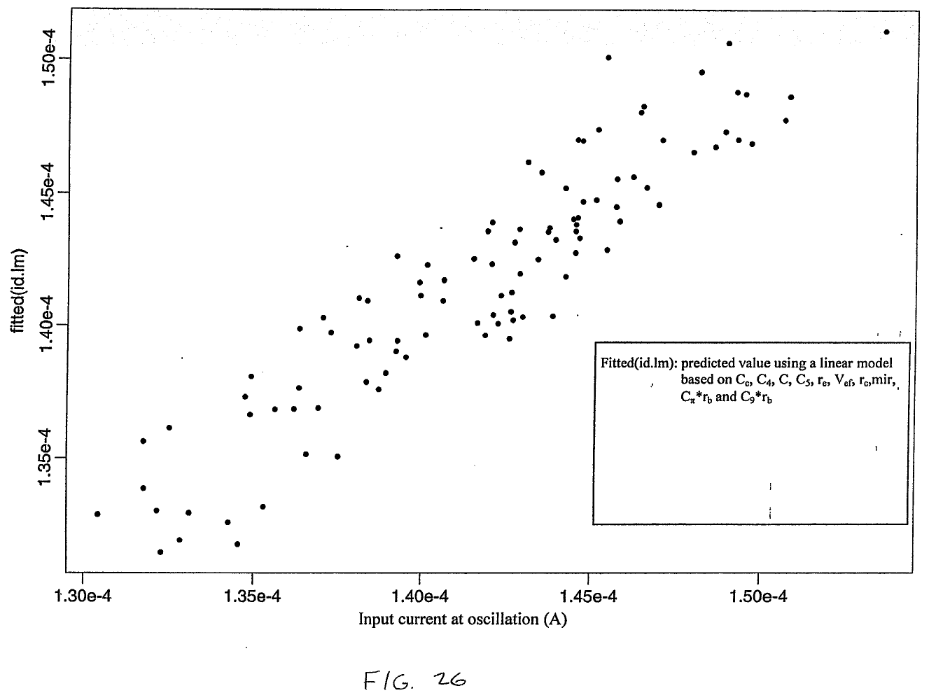

Referring initially to FIGS. 1 and 2, a semiconductor test system 10 in accordance with the present invention will be described. The semiconductor test system 10 provides production compatible test dies 12a-12e on a semiconductor wafer 14 adjacent a plurality of working dies 16 also formed therein. In the following discussion, test dies 12a-12e indicate specific locations on the wafer 14, but a test die in general will be referred to by the reference numeral 12.

Each test die 12 according to the present invention allows DC measurements to be used for monitoring the high frequency parameters of a sample bipolar transistor 18 formed therein. The sample bipolar transistor 18 is substantially identical to a bipolar transistor formed in the working dies 16. The DC measurements from the test dies 12 yield a good correlation to the desired AC bipolar transistor parameters.

The semiconductor test system 10 is used to monitor semiconductor processing at the wafer acceptance level, which helps to detect undesired drifts in key parameters as soon as possible. If problems with the semiconductor processing are observed, the semiconductor wafer 14 could be taken to the laboratory for more detailed analysis.

The semiconductor test system 10 comprises at least one semiconductor wafer 14 comprising a plurality of working dies 16 and at least one test die 12 formed therein. Each of the working dies 16 comprises at least one bipolar transistor 18. The test dies 12 take the place of working dies, and are positioned at various locations on the semiconductor wafer 14, as readily appreciated by one skilled in the art. For example, test die 12c is at a center of the semiconductor wafer 14, and test dies 12a, 12b, 12d and 12e are at a periphery of the semiconductor wafer. The illustrated placement of the test dies 12a-12e is one example, and other placement configurations are acceptable.

The semiconductor test system 10 further comprises a tester 20 for selectively supplying a changing direct current (DC) input signal to a selected test die, such as test die 12b, for example, and for monitoring a DC output signal therefrom. Each test die 12 comprises a test oscillator 30 including at least one sample bipolar transistor 18 substantially identical to the bipolar transistors of the working dies 14.

The test oscillator 30 switches between a non-oscillating state and an oscillating state as the DC input signal changes, and generates the DC output signal to the tester 20 indicative of switching between the non-oscillating state and the oscillating state. As the DC input signal changes, the level of this signal may either increase or decrease.

In one embodiment, the level of the DC input signal increases as the DC input signal changes. Accordingly, the test oscillator 30 switches from the non-oscillating state to the oscillating state as the level of the DC input signal increases. In another embodiment, the level of the DC input signal decreases as the DC input signal changes. Accordingly, the test oscillator 30 switches from the oscillating state to the non-oscillating state as the level of the DC input signal decreases.

Each test die 12 also comprises a bias current generator 32 for generating a changing bias current to the at least one sample bipolar transistor 18 based upon the changing DC input signal provided by the tester 20. The test oscillator 32 switches between the non-oscillating and oscillating states based upon a threshold level of the changing bias current generated for the sample bipolar transistor 18. The threshold level of the changing bias current is correlated with at least one high frequency parameter of the sample bipolar transistor 18.

The at least one high frequency parameter corresponds to at least one of a base resistance and a base-emitter capacitance of the sample bipolar transistor 18, as will be explained in greater detail below. The base resistance of the sample bipolar transistor 18 effects the transition frequency ft of this transistor, and the base-emitter capacitance of the sample bipolar transistor effects the maximum oscillation frequency f_{MAX} of this transistor.

Each test die 12 further comprises a dummy circuit 40 connected to the test oscillator 30 for maintaining a capacitance of the sample bipolar transistor 18 constant as the bias current changes. The dummy circuit 40 comprises at least one second bipolar transistor 42 substantially identical to the sample bipolar transistor 18, as illustrated in FIG. 12. A coupling capacitor 44 connects the second bipolar transistor 42 to the sample bipolar transistor 18.

Still referring to FIG. 12, a second bias current generator 46 generates a second changing bias current to the second bipolar transistor 42 based upon the changing bias current generated for the sample bipolar transistor 18. Each sample bipolar transistor 18 has a first base-emitter capacitance, and the second bipolar transistor 42 has a second base-emitter capacitance. The second changing bias current decreases as the bias current for the sample bipolar transistor 18 increases so that a combined base-emitter capacitance of the sample and second bipolar transistors 18, 46 is relatively constant.

Each test die 12 further comprises a detector circuit 50 connected to an output of the test oscillator 30 for generating the DC output signal to the tester 20. As illustrated in FIG. 16, each detector circuit 50 comprises at least one output bipolar transistor 52 comprising a base, a collector and an emitter. A coupling capacitor 54 connects the base of the output bipolar transistor 52 to the sample bipolar transistor 18. At least one first diode-configured bipolar transistor 56 is connected between the base and the emitter of the output bipolar transistor 52. A plurality of second diode-configured bipolar transistors 58, 60 and 62 are connected between the base and the collector of the output bipolar transistor 52.

Another aspect of the present invention is directed to a method for testing at least one semiconductor wafer 14 comprising a plurality of working dies 14 and at least one test die 12 formed therein. Each of the working dies 14 comprises at least one bipolar transistor. Each test die 12 comprises a test oscillator 30 including at least one sample bipolar transistor 18 substantially identical to the bipolar transistors of the working dies 14.

Referring to the flowchart in FIG. 3, from the start (Block 70), the method preferably comprises supplying a changing DC input signal to the at least one test die 12 at Block 72. The test oscillator 30 is switched between a non-oscillating state and an oscillating state as the DC input signal changes, and generates a DC output signal indicative of switching between the non-oscillating state and the oscillating state at Block 74. The method further includes monitoring the DC output signal from the at least one test die at Block 76. The method may be stopped at Block 78.

General Approach for Developing and Simulating the Test Dies

As discussed above, the test oscillator 30 starts to oscillate as the input bias current is ramped up. The current at which the test oscillator 30 starts to oscillate will be called the input oscillation threshold current I_{inosc}. The voltage at the output of the detector circuit 50 rises with the oscillation amplitude. As will be illustrated in greater detail below, I_{inosc} strongly depends on the base resistance and the collector-base capacitance of the sample bipolar transistor 18. These are two significant parameters affecting f_{MAX} and fₜ, so the input oscillation threshold current is sensitive to both of these parameters.

The test die 12 was simulated for sensitivity to these parameters. Monte Carlo simulations of the test die 12 were done to observe the behavior of I_{inosc} with varying model parameters. The test die 12 was fabricated in UHF2 0.6 μm BiCMOS process developed by Intersil Corporation, which is the current assignee of the present invention. To study the effects of various parameters, several layout variations were fabricated to induce intentional parametric variations.

Bipolar Transistor Characterization and the Fabrication Process

The figures of merit used to characterize the high frequency performance of the sample bipolar transistors 18, namely, the transition or cut-off frequency fₜ and the maximum oscillation frequency f_{MAX}, will now be discussed in greater detail. In addition, the UHF2 process used to design the test dies 12 will also be discussed.

The speed with which a circuit can respond is determined by the circuit configuration as well as the number and type of transistors and passive components in the circuit. Independent of the choice of circuit configuration and passive components, there are unavoidable speed limitations that depend on the bipolar transistor characteristics.

The high frequency performance of all solid-state devices is ultimately limited by transit-time effects. Two main figures of merit (f_{MAX} and fₜ) are used describe the performance of microwave bipolar transistors. Operating frequencies in microwave circuits are typically limited to frequencies that are 5-10 times less than these parameters.

One parameter used to characterize the high frequency behavior of a bipolar transistor is the common-emitter current gain-bandwidth product, sometimes called the transition frequency fₜ. This is defined as the frequency at which the short-circuit common-emitter current gain |h_{fe}(ω)| is approximately equal to unity.

Consideration is given to the current gain at high frequencies based on the simplified hybrid-π equivalent circuit of FIG. 4. All the elements shown in this figure are that of a standard hybrid-π model of a bipolar transistor. The output current is defined as that flowing in a short-circuit from the output (collector) terminal to ground (the standard test condition). As can be seen from the figure, collector-base junction capacitance C_{jc} is effectively in parallel with the base-emitter junction capacitance Cⱼₑ and the diffusion capacitance C_{diff}. The ratio of output current i_{c} to input current i_{b} gives the short-circuit current gain as:

$$\begin{matrix}{h}_{fe} ( ω ) {{\vert}_{{v}_{o} = 0} = \frac{{i}_{C}}{{i}_{b}} \vert}_{{v}_{o} = 0} = \frac{{g}_{m} {V}_{π}}{{i}_{b}} & ( 1 ) \\ = \frac{{g}_{m} {i}_{b} ( {r}_{π} ‖ {C}_{π t} )}{{i}_{b}} & ( 2 ) \\ = \frac{{g}_{m} {r}_{π}}{1 + {sr}_{π} {C}_{π t}} . & ( 3 )\end{matrix}$$

At high-frequencies,

$${h}_{fe} ( ω ) \approx \frac{{g}_{m} {r}_{π}}{{sr}_{π} {C}_{π t}} \qquad ( 4 )$$

where C_{πt} is the sum of all three capacitances C_{diff}, Cⱼₑ and C_{jc}. FIG. 5 shows the plot of h_{fe}(ω) versus frequency, as indicated by reference 31. The 3 dB cut-off frequency, indicated by the dashed line 33, of the current gain is given by

$${f}_{3 dB} = \frac{1}{2 π {r}_{π} ( {C}_{π} + {C}_{jc} )} . \qquad ( 5 )$$

The frequency at which the gain h_{fe}(ω) extrapolates to unity is given by

$$\begin{matrix}{f}_{t} = \frac{{g}_{m}}{2 π {C}_{π t}} . & ( 6 ) \\ ⇒ \frac{1}{2 π {f}_{t}} = \frac{1}{{g}_{m}} ( {C}_{je} + {C}_{jc} + {C}_{diff} ) . & ( 7 ) \\ ⇒ \frac{1}{2 π {f}_{t}} = \frac{{C}_{je} + {C}_{jc}}{{g}_{m}} + {τ}_{b} & ( 8 )\end{matrix}$$

where

$${C}_{diff} = {τ}_{b} \frac{{I}_{C}}{{V}_{T}} = {g}_{m} {τ}_{b}$$

and τ_{b} is the transit time across the base. As can be seen from equation (8), for low values of I_{C}, fₜ is proportional to I_{C} and as the value of I_{C} is increased, it tends to approach fₜ_{ₘₐₓ} where

$${f}_{{t}_{max}} = \frac{1}{2 {πτ}_{b}} . \qquad ( 9 )$$

However, at such high frequencies, the small-signal model becomes invalid and the delay in the base τ_{b} becomes significant. Thus, fₜ depends primarily on I_{C}, Cⱼₑ, C_{jc} and base width plus second-order effects that can be accounted for by using a more accurate model.

Another parameter that characterizes the high frequency operation of the transistor is the maximum oscillation frequency or unity power gain frequency f_{MAX}. In fact, this is often more important than fₜ because fₜ does not include the effect of r_{b}, which often is very important in analog and RF integrated circuit design. The parameter f_{MAX} is a good measure of transistor performance for power gain in amplifiers, oscillators and other related practical applications. Therefore, f_{MAX} gives more information and hence is more relevant.

Consider the small signal equivalent circuit with a source Vₛ, series resistance R_{S} and load resistance R_{L} as illustrated in FIG. 6. Assuming the frequency is high enough that the capacitive current through C_{π}=Cⱼₑ+C_{diff} is much greater than the current through the resistance r_{π}, simple nodal analysis gives the output resistance as

$${r}_{out} = \frac{{C}_{π}}{{C}_{jc} {g}_{m}} . \qquad ( 10 )$$

Since the input resistance at high frequencies (where the reactance of C_{π} is much less than the value of r_{b}) is r_{b}, the high frequency power gain is given by

$${G}_{P} = \frac{{i}_{c}^{2} {R}_{L}}{{i}_{b}^{2} {r}_{bb}} = \frac{{g}_{m}^{2} {R}_{L}}{4 {r}_{bb} {ω}^{2} {C}_{π}^{2}} . \qquad ( 11 )$$

Substituting rₒᵤₜ, for R_{L} (i.e., considering matched output load conditions for maximum power gain) gives

$${G}_{{P}_{max}} = \frac{{g}_{m}}{4 {ω}^{2} {C}_{π} {C}_{jc} {r}_{bb}} . \qquad ( 12 )$$

The maximum oscillation frequency is that for which power gain is equal to unity. Using this condition and approximating fₜ as

$$\frac{{g}_{m}}{2 π {C}_{π}} gives$$

$${f}_{MAX} = \sqrt{\frac{{f}_{t}}{8 π {C}_{jc} {r}_{bb}}} . \qquad ( 13 )$$

If a non-zero emitter resistance rₑ is included, then equation (13) becomes

$${f}_{MAX} = \sqrt{\frac{{f}_{t}}{8 π {C}_{jc} ( {r}_{bb} + {r}_{e} )}} . \qquad ( 14 )$$

This closed-form expression is, of course, an approximation to represent f_{MAX}. In reality, many other parameters can affect f_{MAX}. The parameter f_{MAX} can also be derived from s-parameters. The maximum power gain is given by

$${G}_{{A}_{max}} = {G}_{{P}_{max}} = \frac{{P}_{Load} {\vert}_{{Γ}_{L} = {Γ}_{out}^{*}}}{{P}_{AVS}} \qquad ( 15 )$$

where P_{Load} is the power delivered to load and P_{AVS} is the power available from the source. Using the above definition of maximum power gain and expressing P_{Load} and P_{AVS} in terms of s-parameters, f_{MAX} can be computed as the frequency where |G_{A}_{ₘₐₓ}|=1. Here, it is assumed that transistor must be unconditionally stable (i.e., no oscillations).

From the above equations, it can be seen that both fₜ and f_{MAX} depend on transistor-model parameters. These model parameters strongly depend on the process and its variability. Thus, to ensure a reliable process, f_{MAX} and fₜ should be monitored. From equation (13), f_{MAX} is approximately proportional to

$$\frac{1}{{r}_{b} {C}_{π}} .$$

The assumption in this relation is that C_{jc} is small in magnitude compared to C_{π} and that it has less variability, which is very true in many cases. In addition, C_{jc} can be easily measured using existing methods. This shows that if some DC measurement correlates well with r_{b} and C_{π}, then it can be used to monitor f_{MAX}.

The IC fabrication process used in this analysis is UHF2, a 0.6 μm, 25 GHz BiCMOS technology for mixed-signal and wireless communications applications developed by Intersil Corporation. The BiCMOS UHF2 process was developed to provide high performance, high levels of system integration, low power, and low cost for RF communications products. It was based on a 0.6 μm analog CMOS process that was already in production. Key advantages of a silicon-only BiCMOS process over more advanced processes like SiGe include lower cost and ease of manufacturing.

Another important issue for RF design is the availability of high quality passive components. The UHF2 process includes other features for RF and mixed signal design such as a high quality metal-oxide-metal capacitor, an electrically programmable polysilicon fuse element, increased substrate isolation using an N+ buried layer to isolate the NMOS well regions from the P-substrate, etc.

The process was designed to support RF design applications up to several GHz, and various devices were added such as a trench-isolated NPN bipolar transistor with fₜ and f_{MAX} of at least 25 GHz and BV_{ceo} greater than 3.5 V, two NPN variations providing increased breakdown capability, a precision RF resistor, and a high quality factor spiral inductor. The quality factor Q of the inductor is defined as

$$Q = \frac{{X}_{L}}{{r}_{s}} \qquad ( 16 )$$

where X_{L} is the effective reactance at a particular frequency and rₛ models the series losses in the inductor.

TABLE 1 lists nominal device parameters for three types of NPN transistors. The primary RF device is a high frequency NPN transistor having a selectively implanted collector SIC implant. It can be seen that for high frequency (RF) NPN transistors, fₜ peaks over 25 GHz while f_{MAX} peaks above 35 GHz. This favorable f_{MAX} to fₜ ratio is achieved using a self -aligned double-polysilicon device architecture that minimizes the two primary parasitic components limiting f_{MAX}, namely, base resistance and collector-base capacitance.

TABLE 1

| | High | | Medium | | High | |
|---|---|---|---|---|---|---|
| | Frequency | | Voltage | | Voltage | |
| Parameter | NPN | | NPN | | NPN | |
| f_{T} @ V_{cb} = 1 V | 27 | GHz | 20 | GHz | 11 | GHz |
| f_{MAX} @ V_{cb} = 1 V | 37 | GHz | 30 | GHz | 18 | GHz |
| h_{FE} | 130 | | 120 | | 100 | |
| V_{A} (V) | 18 | | 48 | | 90 | |
| BV_{ceo} (V) | 3.8 | | 5.5 | | 9.9 | |
| BV_{cbo} (V) | 14 | | 16 | | 26 | |
| BV_{ebo} (V) | 2.7 | | 2.7 | | 2.7 | |
| Re (ohm*μm) | 38 | | 38 | | 38 | |
| Rb (ohm*μm) | 470 | | 490 | | 460 | |
| Rc (ohm*μm) | 740 | | 580 | | 1150 | |
| C_{jEB} (fF/μm) | 2.9 | | 2.9 | | 2.9 | |
| C_{jCB} (fF/μm) | 2.1 | | 2.5 | | 1.8 | |
| C_{jCS} (fF/μm) | 2.8 | | 3.4 | | 2.8 | |
| τ_{F} (ps) | 4.1 | | 5.1 | | 5.5 | |

However, this device is limited to a breakdown voltage of slightly over 3.5 V. The high voltage (HV) NPN transistor has a breakdown voltage greater than 9 V. This was done by masking the SIC implant. However, its speed is too low for many applications. Therefore, the medium voltage (MV) NPN transistor was provided by incorporation of an MVBL (medium voltage phosphorous buried layer) to create an intermediate level of collector doping.

TABLE 2 lists some of the passive devices that are offered by the process. The MOMCAP (metal-oxide-metal capacitor) has a small voltage coefficient, while the MOSCAP (metal-oxide-silicon capacitor) has a significant voltage coefficient. Losses in these capacitors can be modeled the same way as in inductors. The Q of capacitors is then given by

$$Q = \frac{{X}_{C}}{{r}_{s}} \qquad ( 17 )$$

where X_{C} is the effective reactance of the capacitor and rₛ is the series resistance.

TABLE 2

| Component | Value | |
|---|---|---|
| Monosilicon | 100, 400, | Ω/sq |
| Resistors | 1500 | |
| Polysilicon Resistor | 24 | Ω/sq |
| Low TCR Poly | 750 | Ω/sq, |
| Resistor | 75 | ppm/° C. |
| Metal-oxide-silicon | 2.4 | fF/μm² |
| Capacitor | | |
| Metal-oxide-metal | 0.46 | fF/μm² |
| Capacitor | | |

MOMCAP has lower series resistance and hence, higher quality factor since it is built with a thicker metal. In addition, MOMCAP has lower capacitive coupling to the silicon substrate than MOSCAP. The low capacitive coupling for all the passive devices is very important for integrated RF design. However, the oxide thickness for MOMCAP is 70 nm and for MOSCAP is 14 nm. Thus, MOMCAP requires approximately 5 times more area than MOSCAP for the same value of capacitance. Both MOMCAP and MOSCAP have comparable variations with respect to the process. Therefore, use of MOMCAP is preferred unless large values of capacitance are required.

The use of a thick oxide layer under the polysilicon resistor and the resistor's high sheet resistance (smaller size) minimize capacitive-substrate coupling. The quality factor Q of an inductor is limited by the series resistive loss in the metal and loss due to capacitive induced currents in the resistive substrate. To minimize series losses in the inductor, a thick 3 μm Metal 3 layer was used. To reduce losses due to capacitive induced currents, a patterned ground shield (PGS) was added to shield the substrate.

To simulate the circuit designed, a simulation tool named Fastrack was used. Fastrack is a customized version of SPECTRE developed by Intersil Corporation in Cadence environment. It includes built in models for various devices available in UHF2. Models for various devices such as inductors, capacitors, MOS transistors, bipolar transistor, etc., were parameterized to allow accurate modeling for any layout geometry. In addition, it includes statistics for the various devices based upon the measured data taken over time. These statistics were used to run Monte Carlo simulations on the circuit.

Design of the Test Dies

Design of the test dies to correlate high frequency parameters f_{MAX} and fₜ to DC measurements will now be discussed. The various iterations of the test dies 12 that were fabricated and tested will also be discussed, along with the issues that were considered when the test die was laid out.

The test oscillator 30 design process starts with defining the oscillation frequency and the amplitude of oscillation. Oscillators can be designed by two different approaches: a negative resistance method (the microwave approach), and a loop gain method (the analog approach).

Both methods eventually lead to equivalent conditions. In the negative resistance method, small-signal and large-signal s-parameters provide all the information needed to design the oscillators. In a negative resistance oscillator, the matching networks at the two ports are referred to as the terminating and the load-matching networks. The load-matching network is the network that determines the frequency of oscillation, and the terminating network is used to provide the proper matching. However, the analysis supporting the present invention uses the loop-gain method, which is to design the test oscillator 30 to satisfy the Barkhausen oscillation criterion.

The test oscillator 30 uses a positive feedback loop that includes an amplifier 80 and a frequency selective feedback network 82. The amplitude of the generated sine wave is limited using a nonlinear mechanism. Either this nonlinear mechanism can be implemented as a separate circuit or the nonlinearities of the amplifying device itself can be used to limit the amplitude.

A general block diagram of a linear oscillator 84 is shown in FIG. 7. It includes the amplifier 80 and the frequency-selective network 82 connected in a positive-feedback loop. From the diagram,

x₀=Axᵢ. (18)

X_{f}=βx₀. (19)

xᵢ=xₛ+x_{f}. (20)

Thus, closed loop gain is given by

$${A}_{f} = \frac{{x}_{0}}{{x}_{s}} . \qquad ( 21 )$$

Combining equations (18) through (20) with equation (21), the closed loop gain is given by

$${A}_{f} ( s ) = \frac{A ( s )}{1 - A ( s ) β ( s )} . \qquad ( 22 )$$

The loop gain is defined by

L(s)=A(s)β(s). (23)

The characteristic equation thus becomes

1−L(s)=0. (24)

If, at some frequency ω₀ the loop gain is unity, then the closed-loop gain of system will be infinite. That is, there will be a finite output signal with zero input signal at this frequency. Such a circuit is called an oscillator. Thus, for an oscillator to oscillate at some frequency ω₀, the magnitude of the loop gain should be unity and the phase should be zero at that frequency. This is known as Barkhausen criterion. It can also be stated as

L(jω₀)=A(jω₀)β(jω₀)=1. (25)

This condition can be stated in two parts as

Real (L(jω₀))=1 (26)

and

Imaginary(L(jω₀))=0. (27)

For the circuit to oscillate at only one frequency, this criterion should be satisfied only at that frequency. In a well-designed oscillator, the frequency is determined by the phase characteristics of the feedback loop. Thus, the stability of frequency of oscillation is determined by the manner in which phase of the feedback loop varies with frequency.

For the oscillations to start |L(jω)| should be made greater than unity which yields poles in the right half of the s-plane. As long as |L(jω)| stays more than unity, the oscillations will keep on growing in amplitude. Eventually, some nonlinear mechanism reduces |L(jω)| which forces the poles to move into the left half of s-plane. When this happens, the amplitude starts to decrease and then the poles move back to the right half s-plane. This process repeats in each cycle with the poles swinging back and forth across the jω-axis. Thus, in some average sense, the poles stay on the jω-axis.

Generally, oscillators are designed so that the magnitude of the loop gain with no oscillations is much greater than unity to ensure that oscillations start. However, as will be seen below, the focus will be on the point where |L(jω)| is exactly equal to unity, that is, to satisfy Barkhausen's criterion as an equality. This validates the use of small-signal techniques for design.

FIG. 8 shows a simple Colpitts oscillator circuit 88 which can be used in the test die 12. The bias details are omitted to emphasize the oscillator's structure. This oscillator 88 utilizes a parallel LC circuit 90 connected between collector and base of the sample bipolar transistor 18 with a fraction of the tuned circuit fed to the emitter. The resistor R models the load resistance of the test oscillator 88 and the output resistance of the transistor 18. The capacitors C₁, C₂ and inductor L form a positive feedback circuit.

The oscillation condition can be determined by replacing the transistor 18 (which is also represented by Q₁) with its equivalent circuit as shown in FIG. 9, where gₘ is the transconductance of the transistor 18. Assume the collector-base capacitance C_{μ} can be neglected because it is shunted by the inductor L at the frequency of operation. The base-emitter capacitance C_{π} can be considered as a part of C₂. In addition, the input resistance r_{π} can be neglected assuming that at the frequency of oscillation

$${r}_{π} >> \frac{1}{ω {C}_{2}} .$$

In FIG. 9, the voltage at node A is given by

V_{A}=sC₂V_{π}×sL+V_{π}=V_{π}(1+s²LC₂). (28)

Summing all currents at node A yields

sC₂V_{π}+gₘV_{π}+(1/R +sC₁)(1+s²LC₂)V_{π}=0. (29)

If oscillations have started then V_{π}≠0. Thus, eliminating V_{π} gives

$${s}^{3} {LC}_{1} {C}_{2} + \frac{{s}^{2} {LC}_{2}}{R} + s ( {C}_{1} + {C}_{2} ) + ( {g}_{m} + 1 / R ) = 0. \qquad ( 30 )$$

Substituting s=jω gives

$$( {g}_{m} + 1 / R - \frac{{ω}^{2} {LC}_{2}}{R} ) + j [ ω ( {C}_{1} + {C}_{2} ) - {ω}^{3} {LC}_{1} {C}_{2} ] = 0. \qquad ( 31 )$$

For sustained oscillations, both real and imaginary parts of equation (31) must be zero. Equating the imaginary part to zero gives a frequency of oscillation as

$${ω}_{0} = \sqrt{\frac{1}{\frac{{LC}_{1} {C}_{2}}{{C}_{1} + {C}_{2}}}} . \qquad ( 32 )$$

Now equating the real part to zero and using the frequency of oscillation gives

gₘR=C₂/C₁. (33)

Thus, for stable oscillations, the gain from the base to collector (gₘR) must be equal to the inverse of the voltage ratio provided by the capacitance divider. For the oscillations to start, the loop gain must be made greater than unity, which gives

gₘR>C₂/C₁. (34)

The average loop gain is reduced to unity as the oscillations start to grow in amplitude as the transistor's nonlinear characteristics reduce the effective value of gₘ.

In a typical Colpitts oscillator, the intrinsic transistor parameters are shunted by external passive elements. The frequency of oscillation and the condition of oscillation thus depend predominantly on the external passive elements. So the simple Colpitts oscillator in its present form is insensitive to intrinsic parameters and hence, to fₜ and f_{MAX}.

Consider a modified Colpitts oscillator circuit 100, as shown in FIG. 10, with capacitor C₂ removed to emphasize the effects of intrinsic transistor parameters. Resistors rₛ and r_{b} are respectively the effective series resistance of the extrinsic inductor L and the base resistance of the transistor 18. C_{π} and r_{π} respectively model the base to emitter capacitance and resistance of the transistor 18.

As discussed above, the devices used for the design are from the UHF2, BiCMOS process. The collector to base capacitor C_{μ} is on the order of fFs and the base to emitter resistor r_{π} is of the order kΩs for the NPN RF transistor in UHF2. The desired frequency of operation for the test structure is around 2-3 GHz because the model of the inductor was known to be valid around those frequencies.

Since the inductor L is on the order of nH, the assumptions made to neglect C_{μ} and r_{π}, at the operating frequency, are justified with C_{π} (typically on the order of pF) replacing C₂.

At node A,

sC_{π}V_{π}+gₘV_{π}+(sC₁+1/R)(V_{π}+sC_{π}V_{π}(r_{beff}+sL))=0 (35)

where r_{beff}=r_{b}+rₛ.

$$⇒ {sC}_{π} + {g}_{m} + L / R + {sC}_{1} + \frac{{sC}_{π} {r}_{beff}}{R} + \frac{{s}^{2} {C}_{π} L}{R} + {s}^{2} {C}_{1} {C}_{π} {r}_{beff} + {s}^{3} {C}_{1} {C}_{π} L = 0. \qquad ( 36 )$$

Substituting s=jω,

$${g}_{m} + \frac{1}{R} - {ω}^{2} {C}_{π} {C}_{1} {r}_{beff} - \frac{{ω}^{2} {C}_{π} L}{R} + jω ( {C}_{1} + {C}_{π} + \frac{{C}_{π} {r}_{beff}}{R} - {ω}^{2} {C}_{1} {C}_{π} L ) = 0. \qquad ( 37 )$$

From the imaginary part of equation (37),

$${ω}_{0}^{2} = \frac{{C}_{π} + {C}_{1} + \frac{{C}_{π} {r}_{beff}}{R}}{{C}_{π} {C}_{1} L} . \qquad ( 38 )$$

Frequency of oscillation=

$${ω}_{0} = \sqrt{\frac{1 + \frac{{r}_{beff} / R}{1 + {C}_{1} / {C}_{π}}}{\frac{{LC}_{1} {C}_{π}}{{C}_{1} {C}_{π}}}} . \qquad ( 39 )$$

Since R is usually greater than the effective base resistance r_{beff} this leads to

$${ω}_{0} ≅ \sqrt{\frac{1}{\frac{{LC}_{1} {C}_{π}}{{C}_{1} + {C}_{π}}}} . \qquad ( 40 )$$

From the real part of equation (37) and using equation (40),

$$\begin{matrix}{g}_{m} + 1 / R = ( {C}_{1} + {C}_{π} + {C}_{π} \frac{{r}_{beff}}{R} ) \frac{{r}_{beff}}{L} + ( {C}_{π} + {C}_{1} + {C}_{π} \frac{{r}_{beff}}{R} ) \frac{1}{{RC}_{1}} . & ( 41 ) \\ ⇒ {g}_{m} R + 1 = \frac{( {C}_{π} + {C}_{1} ) {Rr}_{beff}}{L} + \frac{( {C}_{π} + {C}_{1} )}{{C}_{1}} + \frac{{C}_{π} {r}_{beff}^{2}}{L} + \frac{{C}_{π} {r}_{beff}}{{RC}_{1}} . & ( 42 ) \\ ⇒ {g}_{m} = \frac{( {C}_{π} + {C}_{1} ) {r}_{beff}}{L} + \frac{{C}_{π}}{{C}_{1} R} + \frac{{C}_{π} {r}_{beff}^{2}}{LR} + \frac{{C}_{π} {r}_{beff}}{{C}_{1} {R}^{2}} . & ( 43 )\end{matrix}$$

The last three terms in equation (43) can be neglected because R>>r_{beff} and C₁≧C_{π}. Typically R is on the order of 20-30 kΩ while r_{beff} is a few hundred ohms. This gives

$${g}_{m} = \frac{{I}_{osc}}{{V}_{T}} \approx \frac{( {C}_{π} + {C}_{1} ) {r}_{beff}}{L} . \qquad ( 44 )$$

Equation (44) shows that for the new circuit without external capacitor C₂, the minimum collector current for oscillations is proportional to r_{beff}(C_{π}+C₁), where r_{beff}=r_{b}+rₛ. Normally, rₛ (anywhere from 7-10 Ω for a 7 nH patterned ground shield or PGS inductor) is 10% or less of r_{b} (typically ˜150 Ω) which implies that the minimum bias current for oscillation will be sensitive to r_{b}. This current will also depend on C_{π}, but the sensitivity will depend on the value of C₁ chosen.

As discussed above, fₜ∝1/C_{π} and f_{MAX}∝1\sqrt{r_{b}C_{π}}. From these relations and equation (44), the minimum collector current required for oscillations to start will be correlated with fₜ and f_{MAX}. Thus, the basic concept is to increase the collector current of transistor 18 until it starts to oscillate. The current at which the circuit starts to oscillate is defined as the oscillation threshold current I_{OSC}. This current I_{OSC} will vary if r_{b}, C_{π} and hence, fₜ and f_{MAX}, vary due to the manufacturing process. Repeating the same analysis including a finite emitter resistance gives

$$\begin{matrix}{ω}_{0}^{2} \approx \frac{{C}_{π} + {C}_{1} + {g}_{m} {r}_{e} {C}_{1}}{{C}_{π} {C}_{1} L} and & ( 45 ) \\ {g}_{m} \approx \frac{( {C}_{π} + {C}_{1} ) ( {r}_{beff} + {r}_{e} )}{L} + \frac{{g}_{m} {r}_{e} {C}_{1} ( {r}_{e} + {r}_{beff} )}{L} , & ( 46 )\end{matrix}$$

where the second term in equation (46) is less than the first term by about a factor of 7-10 (assuming C_{π} and C₁ are of the same order, I_{OSC} is less than 1 MA and rₑ is on the order of 15 Ω) and can be often neglected.

The base to emitter capacitor C_{π} is a function of the collector bias current I_{C}. Therefore, the condition of oscillation and the frequency of oscillation will vary as the current I_{C} changes because the value of C_{π} will change. This complicates the relation between I_{OSC} and f_{MAX} because the right hand side of equation (44) starts varying as the bias current is varied. In addition, to get a reasonable sensitivity to C_{π}, its value has to be made comparable to C₁. To address these issues, a dummy or passive circuit 40 was added to the test oscillator 30 to keep the effective value of C_{π} constant as the bias current is varied.

The schematic of the test oscillator 30 with a dummy circuit 40 is shown in FIG. 11. Here, transistor 43 (which is also represented by Q₂) is identical to transistor 18 (which is also represented by Q₁), and capacitor 44 (which is also represented by C₄) is a coupling capacitor between the two transistors. The current source I₂ and the MOS transistor M₂ are used to bias the transistor Q₂, and C_{c} is an extrinsic large capacitor between the collector and emitter. The sum of the two C_{π} of transistor Q₁ and Q₂ can be considered as C₂.

Current source I₃ and DC voltage source V_{g} are used to bias the MOS transistor M₂. The idea is to decrease the current I₂ on the dummy side as the current I₁ in the active circuit is increased, to make it oscillate, while keeping the total current constant. The constant current ensures a relatively constant C₂. Since the total current is now being split between the two branches, a larger value of total current can be used, leading to a larger C₂.

A disadvantage of adding this passive circuit is that the effective base resistance r_{beff} is decreased approximately by a factor of two. This reduces the sensitivity of the current I_{OSC} to base resistance by the same amount, as can be seen by equation (44). Both Q₁ and Q₂ are minimum size RF transistors with length and width of 0.6 μm and 2.5 μm. C₄ is a 4 pF MOMCAP. A MOMCAP was used for C₁ because MOMCAPs have a lower voltage coefficient.

Since the function of the dummy circuit 40 is to supplement the value of C_{π}, it was biased so that it would not affect the active side in its operation. The dummy circuit alone is shown in FIG. 12. MOS transistor M₂ forms a negative feedback loop to provide a stable DC bias for Q₂. A small voltage V_{g} of approximately 0.5 V applied to the gate of M₂ ensures that it always operates in the saturation region. A small bias circuit was designed to provide this gate voltage, as discussed in greater detail below. At low frequencies, capacitor C_{c} acts as an open circuit and hence, has no effect on the DC bias.

However, at high frequencies, this capacitor shorts the collector of Q₂ and the source of M₂ to small-signal ground, thus killing the feedback loop. The high output impedance of M₂ can be considered an open circuit. Therefore, C_{c} was chosen to be a high value MOSCAP of 20 pF. Thus Q₂ presents only its r_{b} and C_{π} as a load to the base of active transistor Q₁. If the sum of currents in Q₁ and Q₂ are kept constant as I₁ is varied, the sum of the base-emitter capacitances of both the transistors is also approximately constant. The (W/L) ratio for M₂ was chosen to be 80 μm/10 μm.

The feedback loop formed by Q₂ and M₂ must be stable. Therefore, to analyze the stability, the frequency response of the circuit shown in FIG. 12 is considered. The circuit shown in FIG. 12 can be broken at node A, as shown in FIG. 13, to calculate the loop gain. The impedance at several ports are shown in FIG. 13 where Z_{T} is the parallel combination of r_{π} and C_{π}, and gₘ₂ is the transconductance of M₂. From FIG. 13,

$$\begin{matrix}{V}_{1} = - \frac{{V}_{x} {g}_{m1}}{{g}_{m2} + {sC}_{c}} and & ( 47 ) \\ {V}_{y} = {g}_{m2} {Z}_{T} {V}_{1} & ( 48 )\end{matrix}$$

where

$${Z}_{T} = \frac{{r}_{π}}{s {C}_{π} {r}_{π} + 1} .$$

Substituting equation (47) in equation (48), gives

$${V}_{y} = - \frac{{g}_{m1} {g}_{m2} {r}_{π}}{( {g}_{m2} + s {C}_{c} ) ( s {C}_{π} {r}_{π} + 1 )} {V}_{x} . \qquad ( 49 )$$

Thus, the loop gain is

$$L ( s ) = \frac{{V}_{y}}{{V}_{x}} = - \frac{{g}_{m1} {g}_{m2} {r}_{π}}{( {g}_{m2} + s {C}_{c} ) ( s {C}_{π} {r}_{π} + 1 )} . \qquad ( 50 )$$

The poles of the loop gain are given by,

$$\begin{matrix}{ω}_{P1} = \frac{{g}_{m2}}{{C}_{c}} & ( 51 ) \\ {ω}_{P2} = \frac{1}{{C}_{π} {r}_{π}} & ( 52 )\end{matrix}$$

Thus, the gain-bandwidth product of the loop gain is given by,

$$G B W = \frac{{g}_{m1} {g}_{m2} {r}_{π}}{{C}_{c}} \qquad ( 53 )$$

The gain-bandwidth product of the loop gain is the frequency where loop gain becomes unity. For the circuit to be stable at all conditions with adequate phase margin, ω_{P2} cannot be much less than GBW. However, as the current in the dummy circuit 40 is decreased to keep the total current constant, the value of r_{π} increases. The increase in r_{π} causes ω_{P2} to go down, decreasing the phase margin. To limit this effect, the value of effective resistance between base and emitter at high frequencies is limited by including a series RC compensation circuit in parallel with r_{π} as shown in FIG. 14.

At DC, capacitor Cₓ acts as an open circuit and it does not affect the circuit. At high frequencies, the capacitor is effectively shorted and the resistance Rₓ is in parallel with r_{π} limiting the effective base to emitter resistance. The value of Cₓ was chosen large enough so that phase shifts due to the pole-zero pair formed by Rₓ Cₓ do not affect the operation of the oscillator circuit.

The value of Rₓ was chosen equal to a typical value of r_{π} (which is around 2.3-2.5 kΩ for the dummy side transistor). This avoids instability for low values of current I₂ or high values of bipolar transistor current gain because even if the value of r_{π} increases, the effective value of base-emitter resistance is limited by Rₓ, thus maintaining an adequate phase margin. The values of Rₓ and Cₓ used in the final design were chosen based on the simulations to be 3 kΩ and 4 pf, respectively. No undesired oscillations were observed in the fabricated circuits.

The bias circuit for the oscillator is shown in FIG. 15. To bias the two bipolar transistors Q₈ and Q₉, PMOS cascode current mirrors were used. These current mirrors were fed by two external current sources to give flexibility in testing. Unlike bipolar transistors which have finite current gain β, MOS current sources do not have inaccuracies in current transfer ratio due to that effect. The advantage of using cascode current sources rather than a simple current mirror is that output resistance is higher by a factor of gₘrₒ. This factor is in the range of 20 to 100 and thus is significant. The disadvantage, however, of using a cascode current mirror is the reduced signal swing at the output node.

The (W/L) transfer ratio from transistors M₅, M₆, M₁₅, M₁₆ to M₇, M₈, M₁₃, M₁₄ was chosen as three to reduce the value of input current needed to bias the transistors. The (W/L) ratio for each of these transistors was then computed from the value of worst-case drain (or collector) current keeping all the transistors in saturation.

The worst-case occurs when all of the current flows in one side of the circuit. The (W/L) values were simulated for verification. To keep a low power supply voltage, in the initial design, the transistors were kept in weak inversion to get low |V_{GS}|. This requires large W/L ratios and so minimum length transistors were used to reduce the total area.

However, Monte Carlo simulations of the circuit revealed that the correlation of the input oscillation threshold current, I_{osc}, to transistor parameters like r_{b} and C_{π} was very low with this design. This apparently occurred because the small PMOS transistor lengths led to large random variations in bias currents due to mismatch. Therefore, the length of the top row (namely M₅, M₇, M₉, M₁₁, M₁₃, M₁₅) of PMOS was increased by a factor of 10.

The larger |V_{GS}| required an increase in the required power supply from 4.5 V to 6 V. This power supply voltage was also supplied externally. Simulations of the circuit with increased channel lengths showed significant improvement in the correlation of I_{osc} to the relevant BJT parameters. The final values of the (W/L) ratio for transistors are shown in TABLE 3.

TABLE 3

| MOS Transistor | (W/L) ratio |
|---|---|
| M₆, M₁₆ | (280 μm/0.7 μm) |
| M₅, M₁₅ | (280 μm/7 μm) |
| M₈, M₁₄ | (840 μm/0.7 μm) |
| M₇, M₁₃ | (840 μm/7 μm) |
| M₉, M₁₁ | (70 μm/7 μm) |
| M₁₀, M₁₂ | (70 μm/0.7 μm) |
| M₄ | (75 μm/0.7 μm) |
| M₃ | (15 μm/0.7 μm) |

The bias circuit for supplying gate voltage to transistor M₂ was designed to give a stable value of V_{g} as shown in FIG. 15. A simple analysis can show that

$${V}_{g} = \frac{{R}_{1}}{{R}_{2} + {R}_{1}} {V}_{B E} . \qquad ( 54 )$$

Simulations showed that a typical value of V_{BE} was 0.88 V. R₁ and R₂ were chosen to be 5 kΩ and 3.8 kΩ respectively to set V_{g} to 0.5 V, which ensures that M₂ operates in saturation. Resistor R₆ was used to reduce the voltage across the collector-base junction of transistor Q₉, whose breakdown voltage was close to 3.5 V. The value of R₆ was 10 kΩ for the design.

Since the gate voltage depends on a ratio of resistors, the effects of any variations in the value of resistors due to process and temperature are cancelled. Transistor Q₈ is a high voltage (HV) device with breakdown voltage greater than 9 V. A simple current mirror 81 formed by M₃ and M₄ was used to bias M₂ as shown in FIG. 15. Current Iₛ is one-fourth of Iₜₒₜ, which can be derived from the (W/L) ratios and from the fact that the currents are being added at node A. Similarly, I₃ is one-fifth of Iₛ based on the (W/L) ratios.

The detector circuit 50 used to detect the onset of oscillations is shown in FIG. 16. With no oscillations, diode-connected transistor 56 (which is also represented by Q₃) holds transistor 52 (which is also represented by Q₄) close to the threshold of conduction. As the oscillation starts, the coupling capacitor 54 (which is also represented by C₅) acts as a short circuit and transistor Q₄ conducts on positive signal peaks. This causes capacitor C₆ to charge up and the voltage at the output Vₒ increases. Thus, the oscillations can be detected by detecting the increase in the output DC voltage.

The time constant R₅C₆ was made larger than the time of oscillation period to ensure small ripple in the output voltage. Nominal values of R₅ and C₆ for the final design were 4 kΩ and 11.67 pF respectively. Using the diode-connected transistor 56 (Q₃) to provide the bias (rather than a voltage divider) allows optimal compensation that automatically tracks changes due to temperature variation. Since the breakdown voltage of Q₄ is slightly greater than 3 V, three diode-connected RF transistors 58 (Q₅), 60 (Q₆) and 62 (Q₇) were connected in series to drop the voltage at the collector of 52 (Q₄). DC analysis of the detector circuit 50 gives

V_{BE3}−V_{BE4}≈I_{C4}R₅. (55)

Transistor Q₄ was designed for a width of 3 μm so that its V_{BE} is slightly lower than that of transistor Q₃, whose width is 2.5 μm. The values of R₃ and R₄ are 4 kΩ and 2 kΩ respectively for the design. Coupling capacitor 54 (C₅) was chosen to be big enough so that it does not affect operation of the oscillator. The final value of C₅ for the design was 5 pF.

The final test-structure schematic including bias circuits and parasitic elements is shown in FIG. 17. Since the oscillator was designed to operate near 3 GHz, parasitic elements such as lead inductances, probe impedance can strongly affect circuit operation. To evaluate their effects, parasitic elements like lead inductances, probe impedances were included in the final schematic. The final circuit was then simulated again to ensure proper operation.

Four revisions of the test structure were built. Each of these revisions had several iterations as will be discussed later. The four revisions are:

1) Revision 0: C₁=0.6 pF, L=7 nH with no RC stabilization network for the dummy circuit 40;

2) Revision 1: C₁=0.6 pF, L=7 Nh;

3) Revision 2: C₁=0.2 pF, L=7 nH; and

4) Revision 3: C₁=0.3 pF, L=5 nH.

These revisions were designed to explore the effect of changing C₁ on the correlation to C_{π} and the effect of decreasing both L and C₁ on input oscillation threshold current. Input oscillation threshold current has to be designed to have some minimum value because it affects the input current in the dummy circuit 40, and the total current in the circuit is constant.

If the current in the dummy circuit 40 is too high, transistor Q₂ will go in high-level injection. In high-level injection, a high concentration of minority carriers in the base increases the effective base width and degrades the high-frequency operation. In addition, the base-emitter capacitance in high-level injection is not exactly proportional to the collector current and increases at a rate between 1× and 2× the increase in collector current.

This will cause problems in keeping the sum of C_{π} of the two transistors constant since C_{π} of the dummy transistor Q₂ will no longer be directly proportional to collector current. The various iterations of each revision were identical except for variations in the devices under test. These different devices were used to introduce some forced variations in the transistor parameters. This was done to demonstrate the effects of various transistor parameters on the input oscillation threshold current. The devices used were as follows.

Device A:

Nominal high frequency (RF) device (L=0.6 μm, W=2.5 μm) with SIC (selectively implanted collector) implant and no MVBL (medium voltage buried layer). This transistor has fₜ of 25 GHz and f_{MAX} of 35 GHz. The SIC implant decreases the effective base-width and thus increases fₜ.

Device B:

RF device with MVBL and SIC implant (L=0.6 μm, W=2.5 μm). The MVBL increases carrier concentration in the collector and thus leads to a lower r_{c} with respect to Device A.

Device C:

A medium voltage (MV) device (L=0.6 μm, W=2.5 μm) with MVBL and no SIC implant. Since it does not have the SIC implant, this devices has a lower fₜ with respect to the nominal device.

Device D:

Standard RF device (L=1 μm W=2.5 μm) with a longer emitter with respect to the Device A and hence, higher value of r_{b}.

Device E:

Standard RF device (L=0.6 μm W=4 μm) with a wider emitter with respect to the nominal device and hence, lower r_{b}.

Device F:

Standard RF device with single base contact (L=0.6 μm W=2.5 μm) to get a higher r_{b} with respect to Device A.

Device G:

Standard RF device with remote base contact (L=0.6 μm, W=2.5 μm), again, to get a higher r_{b} with respect to Device A.

Device H:

Standard RF device (L=0.6 μm, W=2 μm) with lower width that gives a higher r_{b} with respect to nominal device.

The test circuit was laid out in the BiCMOS, UHF2 0.6 μm process technology. The total area of the circuit was 400 μm×500 μm including an on-chip inductor. The input currents and the power supply voltage were externally supplied to increase the flexibility in testing. The on-chip PGS inductor L occupies 10% of the total area of the circuit. All the capacitances connecting to the collector of Q₁ were MOMCAPs because of their smaller voltage coefficient. In addition, because of their higher Quality-factor, MOMCAPs were generally used unless it was a large value capacitance, in which case a MOSCAP was used.

The PMOS current-mirror transistors were laid out carefully to enhance matching, using parallel connected and interdigitated unit transistors. Interdigitization reduces errors caused by gradients in temperature or gate-oxide thickness across the layout.

Metal 3 was used for most wiring because of its high thickness and hence, low sheet resistance. Components, especially the high frequency ones, were placed as close to each other as possible to minimize transmission line effects, which can be important at such frequencies.

Simulation Results and Measured Test Data for the Test Dies

Results of Fastrack simulations of the test structure will now be discussed. In particular, sensitivity of the test structure was analyzed to study the variations in I_{osc} with the variations with various parameters of the circuit. In addition, Monte Carlo simulations were used to study the behavior of I_{osc}, using the built-in statistics for the various models included in the Fastrack simulator. These statistics, obtained from measured data taken over time, were stored as means and variances of assumed normal distributions in the simulator. Each Monte Carlo simulation was done for 100 iterations. The statistics in the simulator predict there is not much variation of key parameters. Anticipating that, some intentional forced variations based on the layout were introduced, as discussed above.

All the simulations were done using the circuit diagram in FIG. 17. FIGS. 18a-18b show simulation results for the voltage at the collector of the active transistor Q₁ (line 93) as the input current I₁ (line 91) is ramped from 800 μA to 170 μA, with a total current of 800 μA in both the transistors. FIG. 18b shows an expanded plot (line 95) of the collector voltage to emphasize the oscillations. The frequency of the oscillations in simulation was found to be approximately 3 GHz, which is close to the designed frequency. The input oscillation threshold current I_{osc} can be easily observed from FIG. 18a. It was found to be 123 μA for this particular case.

FIGS. 19a-19b show a typical detector output (line 97) with the collector voltage (line 101) of transistor Q₁. As the oscillation grows, the voltage at the output of the detector rises (point 99). This can be used to detect the current at the input at which the circuit starts to oscillate I_{osc}.

FIGS. 20a-20b show simulated input current I₁ (line 103) and the collector current I_{c1} (line 105) plotted versus time. FIGS. 21a-21b and 22a-22b show the voltages at the collectors of Q₁ and Q₂, as Iᵢₙ is ramped up (lines 107, 109) and Iₜₒₜ-Iᵢₙ drops (lines 111, 113), without and with the RC stabilization network for the dummy circuit 40. It can be seen from FIGS. 21a-21b that with no RC stabilization, the passive side goes into low-frequency oscillations that do not occur with the RC network. However, there is still small amplitude high frequency oscillation with the RC network that can be removed by using a lower value of Rₓ. These small amplitude oscillations did not affect the performance of the test die 12 as will be discussed below.

TABLE 4 summarizes the variation in I_{osc} caused by changing different device parameters in the model of the transistor or by changing different elements of the circuit, one at a time. The percentage variation is computed with respect to the nominal RF transistor or Device A as described above. In this table, r_{b}, r_{c}, rₑ and t_{f} are the base resistance, collector resistance, emitter resistance and the base transit time of a bipolar transistor respectively. Capacitor C₁ is connected between the collector of Q₁ and ground and C₄ is the capacitor coupling the base of transistor Q₁ to that of transistor Q₂. L is the patterned ground shield (PGS) inductor used in the circuit.

As can be observed from TABLE 4, the designed circuit has maximum sensitivity to r_{b} and t_{f} and very little sensitivity to all other parameters. The test structure also had reasonable sensitivity to inductor L, but the value of the inductance depends on the geometry of the layout and, hence, is a very controlled parameter. Thus, the expected variation is much less than the model parameters.

TABLE 4

| | Input current | Percentage |
|---|---|---|
| Type of | required to start | variation from the |
| Variation | oscillation (μA) | nominal current (%) |
| Nominal RF | 122.6 | 0.0 |
| Device | | |
| r_{b} + 20% | 131.8 | 7.5 |
| r_{c} + 20% | 123.7 | 0.89 |
| rₑ + 20% | 123.5 | 0.73 |
| t_{f} + 20% | 133.8 | 9.14 |
| C₁ + 10% | 125.6 | 2.45 |
| C₄ + 10% | 120.6 | −1.63 |
| L + 10% | 115.7 | −5.63 |

Monte Carlo simulations of the design revealed that increasing the lengths of the top row of PMOS transistors (M₅, M₇, M₉, M₁₁, M₁₃, M₁₅) in the current mirror from their minimum length improved the sensitivity of I_{osc} to relevant parameters. By increasing the lengths of these devices from 0.7 μm to 7 μm, the standard deviation of the left current mirror ratio decreased from 5.8% to 0.1% and 9.86% to 0.3% for the right current mirror. Simulations with increased PMOS device lengths gave an R-squared (goodness of fit) of 0.61 when the input current was fitted to the product of C_{π}*r_{b} as compared to a totally insignificant R-squared of 0.12, for the same model, with 0.7 μm device lengths. R-squared is a goodness of fit measure that results from a linear regression. It is defined as:

$$R - s q u a r e d = 1 - \frac{\sum {( actual value - predicted value )}^{2}}{\sum {( actual value - mean value )}^{2}} \qquad ( 56 )$$

where the predicted value is obtained by defining a model.

An R-squared of 0.6 means that 60% of the variance in the data is described by that model. As more parameters are added to the model, R-squared goes up because more sources of variation are included. In the above simulations, r_{b}, rₑ and t_{f} vary only by 8.53%, 9.8% and 2.42% respectively. Considering this, an R-squared of 0.61 was found to be reasonable.

FIGS. 23 and 25 show the results of Monte Carlo simulations based on the statistics built into Fastrack, to study the expected effects of natural process variations. The values of capacitor C₁ and the inductor L used for these particular simulations were 0.6 pF and 7 nH respectively. FIG. 23 shows the variation of I_{osc} with operating-point base resistance r_{bop1} of transistor Q₁. The correlation coefficient between I_{osc} and r_{bop1} was found to be 0.732.

The figure also shows the mean value, standard deviation and percentage variation of the base resistance r_{bop1}. The percentage variation is defined as the ratio of standard deviation to the mean. A simulation circuit, as shown in FIG. 24, was built to allow Monte Carlo simulations for studying the variation of f_{MAX} with I_{osc}. For each iteration of the transient simulation, an AC sweep for the two-port configuration of Q₁ was used to compute the s-parameters using the customized Cadence tool. The high frequency characteristic f_{MAX} was then computed using these s-parameters. FIG. 25 shows the plot of maximum oscillation frequency f_{MAX} versus I_{osc}.

The correlation coefficient between them was −0.794 for this configuration of the test structure (C₁=0.6 pF and L=7 nH). The mean, standard deviation and percentage variation of f_{MAX} of transistor Q₁ are noted in the figure. The percentage variation of I_{osc} obtained from the simulations was 3.56% caused by the Fastrack-predicted variation of 3.65% and 8.61% in f_{MAX} and r_{bop1} respectively of the transistor Q₁.

TABLE 5

| Parameters used in | |
|---|---|
| model to predict | R-squared |
| C₂*r_{beff} | 0.61 |
| (C₂ + C₁)*r_{beff} | 0.64 |
| C_{c}, C₄, Cₓ, C₅, rₑ, | 0.86 |
| V_{ef}, r_{c}, Mir, C₂*r_{beff} | |
| and C₁*r_{beff} | |

The values of I_{osc} obtained from the simulation were fitted to a model. FIG. 26 plots the fitted value of current with I_{osc} as obtained from simulations. The fitted value of the current was predicted using linear regression-based model including various sets of elements in the circuit and device parameters. The accuracy of the model determines the R-squared value. Comparing the R-squared value for different sets of elements helps to identify the components most strongly affecting I_{osc}.

TABLE 5 shows the R-squared value for different models. Here, C_{c}, C₄, Cₓ, C₅ and C₁ are as defined in FIG. 17 and rₑₘₚ, V_{ef}, r_{cmp} are emitter resistance, forward early voltage, collector resistance of the bipolar transistor respectively. The variable r_{beff} is the effective base resistance and C₂ is the sum of C_{π} of transistors Q₁ and Q₂.

Mir is the current mirror ratio at a low value of current when the circuit is not oscillating. As more elements are added in the model, the value of R-squared increases because more and more variation is accounted by adding more elements to the model. The table shows that 61% of the variation in the value of I_{osc} was due to the product C_{2*}r_{beff}.

TABLE 6 shows the means, standard deviations and percentage variations of base resistance r_{b}, current at oscillation I_{osc} and base-transit time t_{f} for various iterations of the Revision 1 circuit with C₁=0.6 PF and L=7 nH, as discussed above. This data was obtained from Monte Carlo simulations of several iterations of the circuit.

As can be seen from the table, the value of I_{osc} obtained from simulation follows the expected pattern, that is, increase in base resistance or base transit time requires higher I_{osc}. The percentage variation, as defined before, is the ratio of standard deviation to the mean. The percentage variations obtained in I_{osc} are reasonable considering that there is little variation in the base resistance and base transit time.

All the data obtained from the different Monte Carlo simulations were analyzed by writing programs in Splus. Splus is a statistical software language from Mathsoft.

TABLE 6

| | | | | | | | Input current required | | |
|---|---|---|---|---|---|---|---|---|---|
| | Base resistance of W₁ (Ω) | | | Base Transit time (pS) | | | for oscillation (μA) | | |
| | | | % | | | % | | | % |
| Type of | | Standard | Varia- | | Standard | Varia- | | Standard | Varia- |
| Device | Mean | Deviation | tion | Mean | Deviation | tion | Mean | Deviation | tion |
| Device | 100.9 | 8.7 | 8.61 | 6.13 | 0.16 | 2.62 | 112.7 | 5.77 | 5.13 |
| E | | | | | | | | | |
| Device | 157.9 | 13.46 | 8.53 | 6.55 | 0.16 | 2.42 | 142 | 5.03 | 3.53 |
| A | | | | | | | | | |
| Device | 195 | 16.74 | 8.6 | 7.24 | 0.16 | 2.17 | 176 | 7.6 | 4.32 |
| H | | | | | | | | | |
| Device | 155.9 | 12.94 | 8.3 | 8.9 | 0.22 | 2.46 | 206 | 9.2 | 4.37 |
| C | | | | | | | | | |

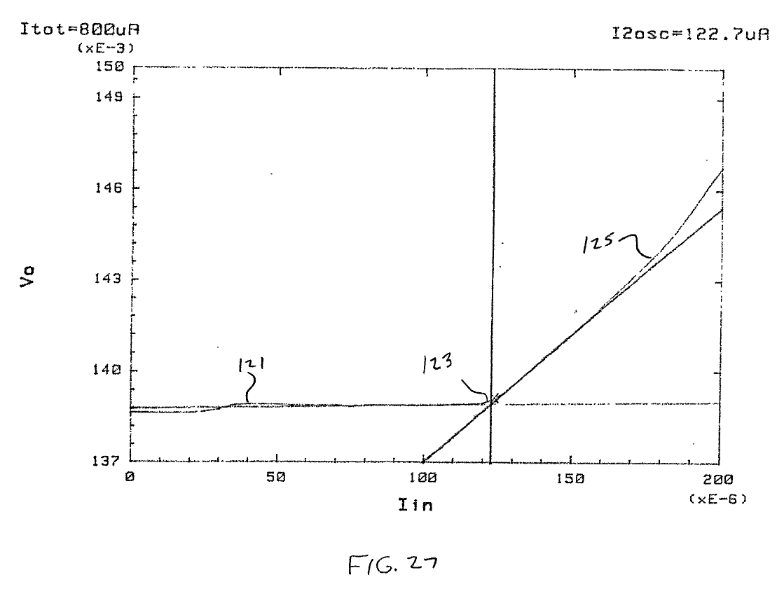

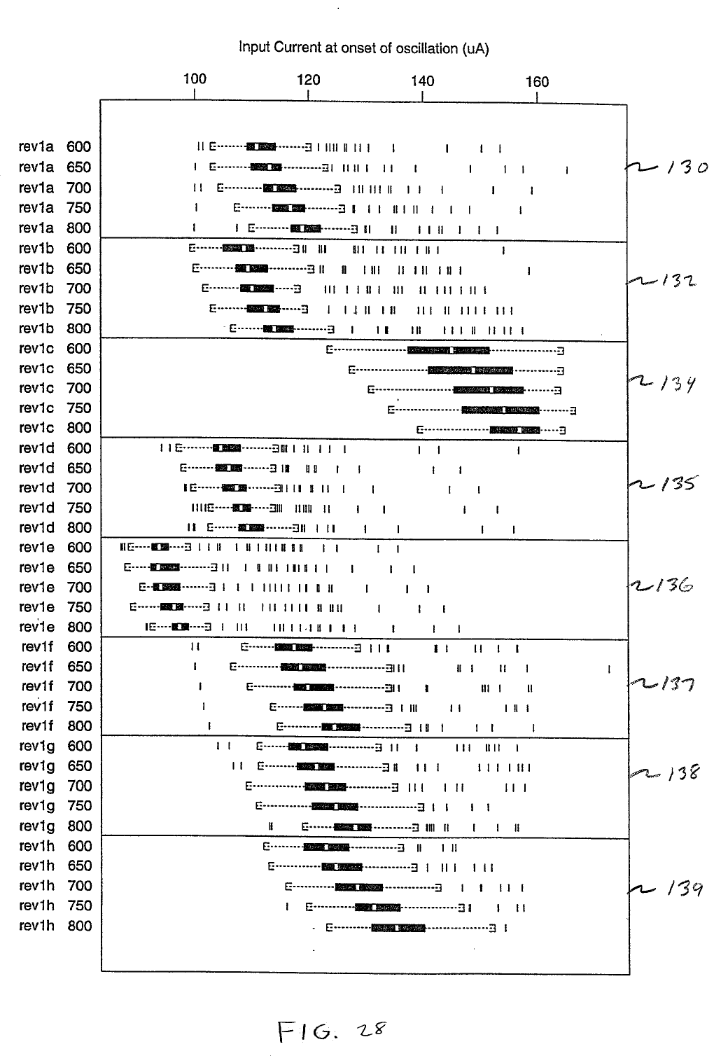

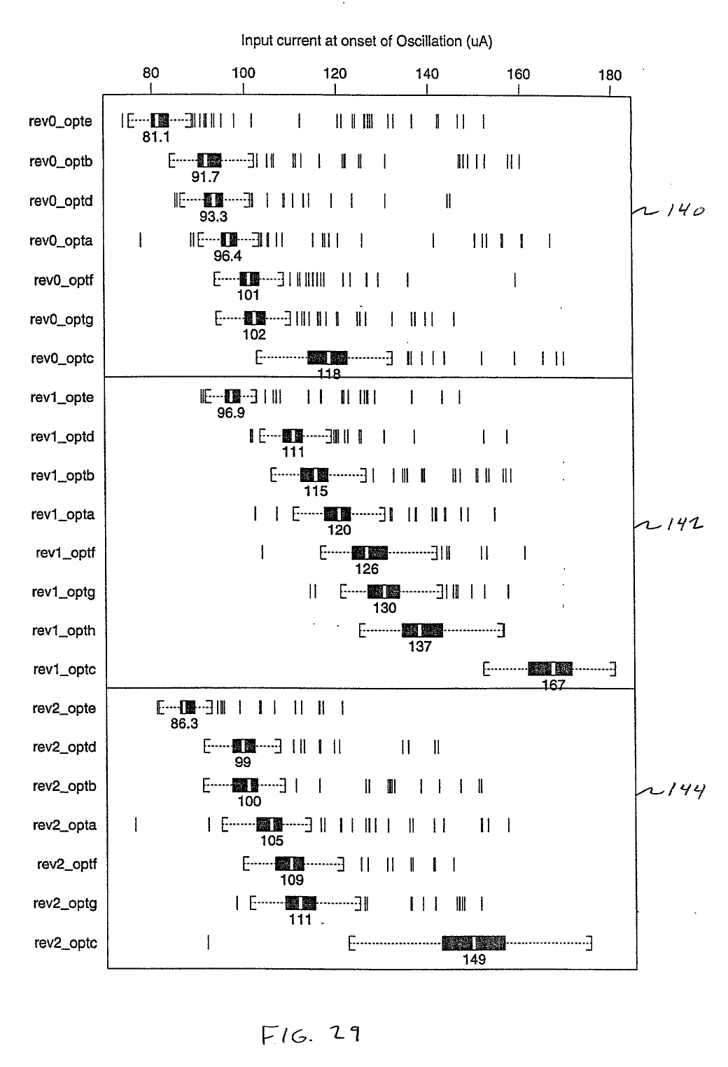

FIG. 27 shows the voltage output (line 121) of the test structure measured, using a DC probe, as Iᵢₙ₂ was increased. As shown in the simulations, the oscillation point 123 can be detected when the voltage begins to rise, as indicated by reference 125. The exact threshold was determined using two techniques: (1) by fitting lines through each of the two regions of the plot and finding their point of intersection, and (2) by detecting the point where the voltage is 0.1 mV higher than the voltage in the flat region before the oscillation starts.

The values of currents measured by the above two techniques were found to be strongly correlated and so either of them is a good enough measure to detect the current at oscillation. Again, Splus was used to analyze the above-obtained data.

FIG. 28 shows box plots of the measured input current at oscillation for all the iterations of Revision 1 (C₁=0.6 pF, L=7 nH) at different values of total currents between 600 μA and 800 μA. A box plot represents the measured data from all the wafers for one particular configuration as a normal distribution, with the median marked in the middle as a white stripe. Here, the x-axis lists different iterations, at different values of total currents in μA, of Revision 1, namely:

rev1a 130: Revision 1 with Device A (the nominal RF device with SIC implant and no MVBL);

rev1b 132: Revision 1 with Device B (RF device with both SIC implant and MVBL);

rev1c 134: Revision 1 with Device C (MV device with MVBL and no SIC implant);

rev1d 135: Revision 1 with Device D (RF device with longer length);

rev1e 136: Revision 1 with Device E (RF device with larger width);

rev1f 137: Revision 1 with Device F (RF device with single base contact);

rev1g 138: Revision i with Device G (RF device with remote base contact); and

rev1h 139: Revision 1 with Device H (RF device with smaller width)

These devices were described in detail above. As can be seen from FIG. 28, the trends for all values of total current among different iterations are quite similar, except slightly higher current is required for oscillation to start at 800 μA than at 600 μA. This happens because I_{osc} depends on the sum of the C_{π}s of transistors Q₁ and Q₂, which is a function of the total current supplied to the circuit.

The advantage of using 600 μA rather than 800 μA is that the passive transistor Q₂ does not operate in strong high-level injection. These trends demonstrate that a lower value of total current can be used without affecting the operation of the test structure significantly.

FIG. 29 shows box plots of measured current for all the iterations of each revision with different devices at a total input current of 800 μA. As the base resistance is increased or the maximum frequency of oscillation f_{MAX} is decreased, the value of I_{osc} increases. In the figure, various iterations or options are the same as described before for Revision 1 and rev0 140, rev1 142, rev2 144 are Revision 0, Revision 1 and Revision 2 respectively. For example, rev0_opta is iteration A, or iteration with Device A, of Revision 0.

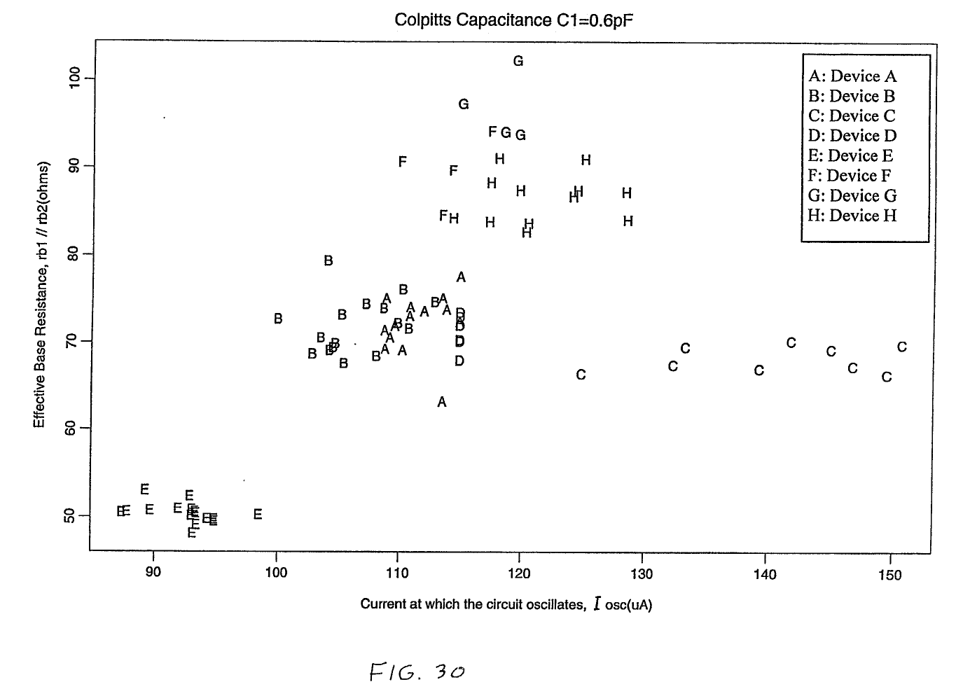

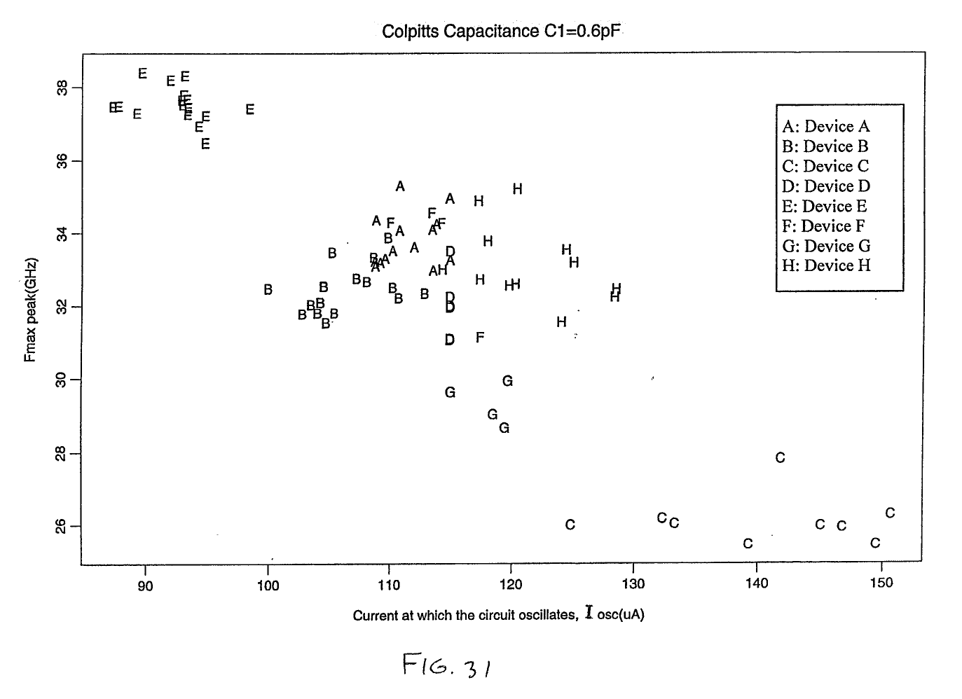

The DC data previously discussed were correlated with measured AC data using an Splus program. The AC data were obtained by s-parameter measurements of devices from the same dies as the test structure. FIG. 30 shows effective base resistance, which is the parallel combination of the base resistances of Q₁ and Q₂, plotted vs. I_{osc}. Since the plot is on a base resistance scale, points corresponding to Device C have the same y-coordinates as those of Device A. As expected, the current I_{osc} tends to increase with base resistance.

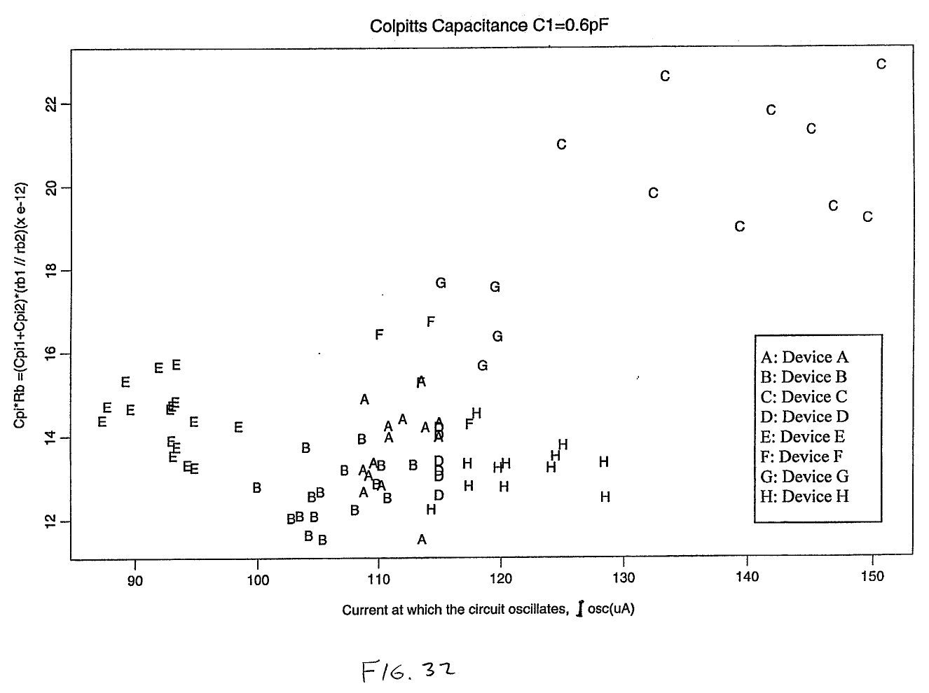

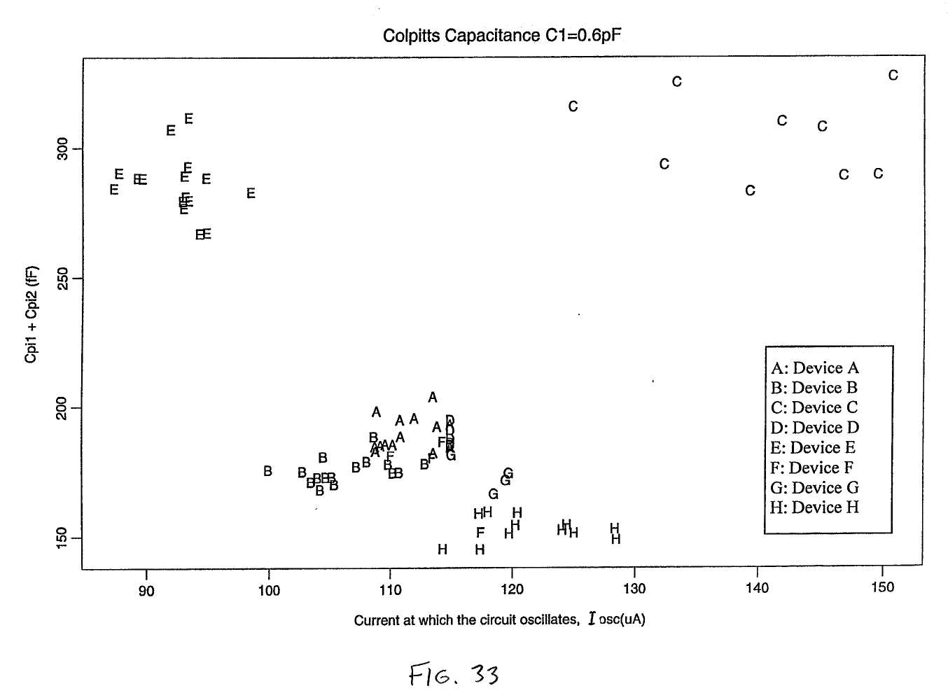

FIG. 31 is a plot of maximum oscillation frequency f_{MAX} obtained from the measured s-parameters vs. I_{osc}. Here also, as expected, the current I_{osc} tends to increase with decreasing f_{MAX}. Finally, I_{osc} was plotted versus a simple model based on the product C_{π}*r_{b} as shown in FIG. 32. Here, r_{b} is the parallel combination of r_{b1} and r_{b2} while C_{π} is the sum of C_{π} of the two transistors. The values of C_{π}, r_{b1} and r_{b2} were again obtained from the AC measurements.

As discussed above, f_{MAX} is approximately proportional to ¹/ᵣ_{_{eb}}_{C}_{_{π}}. Comparing FIG. 32 with FIG. 31, it seems that the above relation holds except for the displaced E devices, which ideally should have lower y-coordinates in FIG. 32 than the A and B devices. To see why this may have happened, note that the C_{π}-extraction program gave a higher value of C_{π} for E devices than A and B devices as shown in FIG. 33. In fact, as can be observed from the figure, the values of extracted C_{π} for E devices were approximately equal to that for the C devices, which are actually much slower. Thus, apparently there was some error in the C_{π}-extraction that led to the displaced E devices in FIG. 32.

Conclusion

The test die 12 allows DC measurements that correlate to key high frequency parameters of a bipolar transistor 18. These DC measurements can be used to monitor the manufacturing process to detect drift in these process parameters. The semiconductor wafer test system 10 was fabricated and was found to meet all the target specifications. The test oscillator 30 starts to oscillate as the input current is increased from zero. The rise in the output voltage of a detector circuit 50 can be used to determine the input current at which the oscillations start. This input current, also referred as input oscillation threshold current or I_{osc}, is strongly affected by the base resistance and base-emitter capacitance of the transistor under test.

Simulations of the circuit, with varied parameters in the transistor model, showed that I_{osc} varied by 7.5% for 20% variation in base resistance and by 9.5% for 20% variation in the base transit time. In addition, Monte Carlo simulations of the circuit, using statistics built into the simulation tool, showed that the correlation coefficient between I_{osc} and f_{MAX} was −0.794. These results indicate that the designed test die 12 is sensitive to f_{MAX} base resistance and base-transit time.

As was observed from the measured data, there were small variations in the process. This resulted in little scatter in the data due to the natural process variations, reducing the statistical significance of the measured data. There was some scatter in data due to the intentionally induced layout variations. However, these were not enough to confidently fit the data into a model. Three revisions of the test structure were fabricated. The Revision 0 circuit was found to give inconsistent results in DC measurements, which was possibly because Revision 0 did not have any RC stabilization circuit. Results with Revision 1 and Revision 2 were indistinguishable as there was not enough scatter to reliably prove which one was better. However, Revision 1 required slightly higher value of I_{osc} than Revision 2.

Many modifications and other embodiments of the invention will come to the mind of one skilled in the art having the benefit of the teachings presented in the foregoing descriptions and the associated drawings. Therefore, it is to be understood that the invention is not to be limited to the specific embodiments disclosed, and that modifications and embodiments are intended to be included within the scope of the appended claims.

That which is claimed is:

1. A semiconductor test system comprising:
at least one semiconductor wafer comprising a plurality of working dies and at least one test die formed therein, each of said working dies comprising at least one bipolar transistor; and
a tester for selectively supplying a changing direct current (DC) input signal to said at least one test die and monitoring a DC output signal therefrom;
said at least one test die comprising a test oscillator including at least one sample bipolar transistor substantially identical to the bipolar transistors of said working dies;
said test oscillator switching between a non-oscillating state and an oscillating state as the DC input signal changes, and generating the DC output signal to said tester indicative of switching between the non-oscillating state and the oscillating state.

2. A semiconductor test system according to claim 1, wherein the changing DC input signal comprises an increasing DC input signal.

3. A semiconductor test system according to claim 1, wherein said at least one test die further comprises a bias current generator for generating a changing bias current to said at least one sample bipolar transistor based upon the changing DC input signal.

4. A semiconductor test system according to claim 3, wherein said test oscillator switches between the non-oscillating and oscillating states based upon a threshold bias current which correlates with at least one high frequency parameter of said at least one sample bipolar transistor.

5. A semiconductor test system according to claim 4, wherein the at least one high frequency parameter of said at least one sample bipolar transistor corresponds to at least one of a maximum oscillation frequency and a transition frequency.

6. A semiconductor test system according to claim 3, wherein said at least one test die further comprises a dummy circuit connected to said test oscillator for maintaining a capacitance of said at least one sample bipolar transistor constant as the bias current changes.

7. A semiconductor test system according to claim 6, wherein said dummy circuit comprises:
at least one second bipolar transistor substantially identical to said at least one sample bipolar transistor;
a coupling capacitor connecting said at least one second bipolar transistor to said at least one sample bipolar transistor; and
a second bias current generator for generating a second changing bias current to said at least one second bipolar transistor based upon the changing bias current generated for said at least one sample bipolar transistor.

8. A semiconductor test system according to claim 7, wherein said at least one sample bipolar transistor has a first base-emitter capacitance and said at least one second bipolar transistor has a second base-emitter capacitance; and wherein the second changing bias current decreases as the bias current for said at least one sample bipolar transistor increases so that a combined base-emitter capacitance of said at least one sample and second bipolar transistors is relatively constant.

9. A semiconductor test system according to claim 1, wherein said at least one test die further comprises a detector circuit connected to an output of said test oscillator for generating the DC output signal to said tester.

10. A semiconductor test system according to claim 9, wherein said detector circuit comprises:
at least one output bipolar transistor comprising a base, a collector and an emitter;
a coupling capacitor connecting the base of said at least one output bipolar transistor to said at least one sample bipolar transistor;
at least one first diode-configured bipolar transistor connected between the base and the emitter of said at least one output bipolar transistor; and
at least one second diode-configured bipolar transistor connected between the base and the collector of said at least one output bipolar transistor.

11. A semiconductor test system according to claim 1, wherein said test oscillator comprises a Colpitts oscillator.

12. A semiconductor wafer comprising:
a semiconductor substrate;
a plurality of working dies on said semiconductor substrate, each of said working dies comprising at least one bipolar transistor; and
at least one test die on said semiconductor substrate, and comprising a test oscillator including at least one sample bipolar transistor substantially identical to the bipolar transistors of said working dies;
said test oscillator switching between a non-oscillating state and an oscillating state as a DC input signal being applied thereto changes, and generating a DC output signal indicative of switching between the non-oscillating state and the oscillating state.

13. A semiconductor wafer according to claim 12, wherein the changing DC input signal comprises an increasing DC input signal.

14. A semiconductor wafer according to claim 12, wherein said at least one test die further comprises a bias current generator for generating a changing bias current to said at least one sample bipolar transistor based upon the changing DC input signal.

15. A semiconductor wafer according to claim 14, wherein said test oscillator switches between the non-oscillating and oscillating states based upon a threshold bias current which correlates with at least one high frequency parameter of said at least one sample bipolar transistor.

16. A semiconductor wafer according to claim 15, wherein the at least one high frequency parameter of said at least one sample bipolar transistor corresponds to at least one of a maximum oscillation frequency and a transition frequency.

17. A semiconductor wafer according to claim 14, wherein said at least one test die further comprises a dummy circuit connected to said test oscillator for maintaining a capacitance of said at least one sample bipolar transistor constant as the bias current changes.

18. A semiconductor wafer according to claim 17, wherein said dummy circuit comprises:
at least one second bipolar transistor substantially identical to said at least one sample bipolar transistor;
a coupling capacitor connecting said at least one second bipolar transistor to said at least one sample bipolar transistor; and
a second bias current generator for generating a second changing bias current to said at least one second bipolar transistor based upon the changing bias current generated for said at least one sample bipolar transistor.

19. A semiconductor wafer according to claim 18, wherein said at least one sample bipolar transistor has a first base-emitter capacitance and said at least one second bipolar transistor has a second base-emitter capacitance; and wherein the second changing bias current decreases as the bias current for said at least one sample bipolar transistor increases so that a combined base-emitter capacitance of said at least one sample and second bipolar transistors is relatively constant.

20. A semiconductor wafer according to claim 12, wherein said at least one test die further comprises a detector circuit connected to an output of said test oscillator for generating the DC output signal.

21. A semiconductor wafer according to claim 20, wherein said detector circuit comprises:
at least one output bipolar transistor comprising a base, a collector and an emitter;
a coupling capacitor connecting the base of said at least one output bipolar transistor to said at least one sample bipolar transistor;
at least one first diode-configured bipolar transistor connected between the base and the emitter of said at least one output bipolar transistor; and
at least one second diode-configured bipolar transistor connected between the base and the collector of said at least one output bipolar transistor.

22. A semiconductor wafer according to claim 12, wherein said test oscillator comprises a Colpitts oscillator.

23. A method for testing a semiconductor wafer comprising a plurality of working dies and at least one test die formed therein, each of the working dies comprising at least one bipolar transistor; the at least one test die comprising a test oscillator including at least one sample bipolar transistor substantially identical to the bipolar transistors of the working dies, the method comprising:
supplying a changing direct current (DC) input signal to the at least one test die so that the test oscillator switches between a non-oscillating state and an oscillating state;
generating a DC output signal indicative of switching between the non-oscillating state and the oscillating state; and
monitoring the DC output signal from the at least one test die.

24. A method according to claim 23, wherein the supplying and monitoring is performed using a tester connected to the at least one test die.

25. A method according to claim 23, wherein a level of the DC input signal increases as the DC input signal changes.

26. A method according to claim 23, wherein the at least one test die further comprises a bias current generator for generating a changing bias current to the at least one sample bipolar transistor based upon the changing DC input signal.

27. A method according to claim 26, wherein the test oscillator switches between the non-oscillating and oscillating states based upon a threshold bias current which correlates with at least one high frequency parameter of the at least one sample bipolar transistor.

28. A method according to claim 27, wherein the at least one high frequency parameter of the at least one sample bipolar transistor corresponds to at least one of a maximum oscillation frequency and a transition frequency.

29. A method according to claim 26, wherein the at least one test die further comprises a dummy circuit connected to the test oscillator for maintaining a capacitance of the at least one sample bipolar transistor constant as the bias current changes.

30. A method according to claim 29, wherein the dummy circuit comprises at least one second bipolar transistor substantially identical to the at least one sample bipolar transistor; and a coupling capacitor connecting the at least one second bipolar transistor to the at least one sample bipolar transistor; and further comprising:
generating a second changing bias current using a second bias current generator, for the at least one second bipolar transistor based upon the changing bias current generated for the at least one sample bipolar transistor.

31. A method according to claim 30, wherein the at least one sample bipolar transistor has a first base-emitter capacitance and the at least one second bipolar transistor has a second base-emitter capacitance; and wherein the second changing bias current decreases as the bias current for the at least one sample bipolar transistor increases so that a combined base-emitter capacitance of the at least one sample and second bipolar transistors is relatively constant.

32. A method according to claim 23, wherein the at least one test die further comprises a detector circuit connected to an output of the test oscillator for generating the DC output signal.
